(19) United States
(12) Patent Application Publication
(10) Pub. No.: US 2012/0018792 A1
(43) Pub. Date: Jan. 26, 2012

(54) NONVOLATILE SEMICONDUCTOR MEMORY DEVICE AND METHOD OF MANUFACTURING THE SAME

(76) Inventors: Daisuke Matsushita, Kanagawa-Ken (JP); Ryuji Ohba, Kanagawa-Ken (JP); Yuichiro Mitani, Kanagawa-Ken (JP)

(21) Appl. No.: 13/146,312

(22) PCT Filed: Jan. 21, 2010
(86) PCT No.: PCT/JP2010/050701

§ 371 Date: Oct. 12, 2011

(30) Foreign Application Priority Data
Jan. 28, 2009 (JP) 2009-016285

(51) Int. Cl. H01L 29/788; H01L 21/28

(52) U.S. Cl. 257/316; 438/591; 257/324; 257/E21.21; 257/E29.3

(57) ABSTRACT

A method of manufacturing a nonvolatile semiconductor memory device according to an embodiment, includes: forming a first insulating film on a semiconductor substrate; forming a charge trapping film on the first insulating film, the forming of the charge trapping film including; forming a first nitride layer on the first insulating film at a heat treatment temperature of 550° C. or higher, forming a first oxynitride layer on the first nitride layer by oxidizing a surface of the first nitride layer, and forming a second nitride layer on the first oxynitride layer; forming a second insulating film on the charge trapping film; and forming a control gate on the second insulating film.

### CROSS-REFERENCE TO RELATED APPLICATION

This application is based upon and claims the benefit of priority from prior Japanese Patent Application No. 2009-16285 filed on Jan. 28, 2009 in Japan and PCT/JP2010/050701 filed on Jan. 21, 2010 in Japan, the entire contents of which are incorporated herein by reference.

### FIELD

Embodiments described herein relate generally to a nonvolatile semiconductor memory device and a method of manufacturing the same.

### BACKGROUND

A nonvolatile memory device (also referred to as a nonvolatile memory) is a recording device that enables data retention even where the power supply is off, by utilizing the characteristics of a ferroelectric material that can blow a fuse of the device with an electric current, can retain charges in an electrode called floating gate surrounded by an insulating material, or can hold positive/negative charges. Types of nonvolatile memories include mask ROM, PROM, EPROM, EEPROM, PRAM, FeRAM, and ReRAM. Particularly, NAND flash memories (hereinafter also referred to as flash EEPROMs) that solved the problem of slow writing and erasing of EPRAMs by performing collective erasing (“flash”) by the block made nonvolatile memories rapidly grow to monopolize the LSI market in combination with the market expansion of portable devices and digital cameras, and now occupies a large proportion of the nonvolatile memory production.

The fundamental device structure of a flash EEPROM is characteristically a MONOS (Metal-Oxide-Nitride-Oxide-Silicon) structure or a SONOS (Silicon-Oxide-Nitride-Oxide-Silicon) structure that has a floating gate (FG) or a charge trapping film on a tunnel insulating film. The floating gate is made of polysilicon covered with an insulating film, and the charge trapping film is a silicon nitride film covered with an insulating film. The voltage (the control voltage) to be applied to a control gate that is formed on the floating gate or the charge trapping film to be the charge storage film and surrounds an interelectrode insulating film or a block insulating film is controlled so that electrons are injected from the substrate into the floating gate or the charge trapping layer via the tunnel insulating film by FN (Fowler-Nordheim) tunneling (writing), or electrons are pulled out from the floating gate via the tunnel insulating film (erasing in FG structures, MONOS structures, and SONOS structures). Alternatively, the control voltage is controlled so that holes are injected into the charge trapping film, and the holes and electrons annihilate each other (auxiliary erasing in MONOS structures and SONOS structures). In this manner, the threshold values of memory cells are changed.

To further expand the existing market and create a new market, flash memories are expected to consume less power, have larger capacities, and operate at higher speeds. To produce flash memories having such features, intensive research and development efforts are being made. To realize lower power consumptions, larger capacities, and higher operation speeds, MOSFETs have been miniaturized, so have memory devices of the FG type, the MONOS type and the SONOS type. Therefore, the electrical film thicknesses of the insulating films of the respective devices should be reduced. Particularly, MONOS and SONOS memory devices have excellent retention characteristics to trap charges in defective levels formed in insulating films, and are expected as future flash memories.

However, where the film thickness of the tunnel insulating film, the interelectrode insulating film, or the block insulating film becomes smaller due to miniaturization, retention characteristics are degraded even in a MONOS or SONOS memory device. To counter this problem, a high-k material is used for the tunnel insulating film, the interelectrode insulating film, or the block insulating film, so that the physical film thickness is increased while the electrical film thickness is reduced. For example, JP-A 10-270664(KOKAI) discloses a semiconductor memory in which a silicon film doped with an impurity is used as the floating gate, a stacked structure consisting of a silicon nitride film and a silicon oxide film is used as the interelectrode insulating film, and a silicon film doped with an impurity is used as the control gate.

However, where future flash memories are expected to have multilayer structures or three-dimensional structures, and a technique for scaling the bit cost per volume needs to be developed, it is difficult to prevent degradation of charge retention characteristics due to miniaturization by increasing physical film thicknesses.

### BRIEF DESCRIPTION OF THE DRAWINGS

FIGS. 1(a) and 1(b) are diagrams for explaining a first method for improving the charge retention characteristics according to an embodiment.

FIGS. 2(a) and 2(b) are diagrams for explaining a second method for improving the charge retention characteristics according to an embodiment.

FIGS. 3(a) through 3(f) are cross-sectional views showing procedures for manufacturing a nonvolatile semiconductor memory device according to a first embodiment.

FIGS. 4(a) through 4(d) are cross-sectional views showing procedures for manufacturing a nonvolatile semiconductor memory device according to the first embodiment.

FIGS. 5(a) through 5(d) are cross-sectional views showing procedures for manufacturing a nonvolatile semiconductor memory device according to the first embodiment.

FIGS. 6(a) and 6(b) are cross-sectional views showing procedures for manufacturing a nonvolatile semiconductor memory device according to the first embodiment.

FIG. 7 is a diagram showing the charge retention characteristics of the nonvolatile semiconductor memory device according to the first embodiment.

FIG. 8 is a diagram for explaining how the charge center is determined in a nonvolatile semiconductor memory device.

FIG. 9 is a diagram showing oxygen distributions in charge trapping films.

FIG. 10 is a diagram showing the dependence of the oxidizing conditions on the trapped charge density where the silicon nitride layer is formed at a high temperature.

FIG. 11 is a diagram showing the dependence of the oxidizing conditions on the trapped charge density where the silicon nitride layer is formed at room temperature.

FIGS. 12(a) through 12(f) are cross-sectional views showing procedures for manufacturing a nonvolatile semiconductor memory device according to a second embodiment.

FIGS. 13(a) through 13(d) are cross-sectional views showing procedures for manufacturing a nonvolatile semiconductor memory device according to the second embodiment.

FIGS. 14(a) through 14(d) are cross-sectional views showing procedures for manufacturing a nonvolatile semiconductor memory device according to the second embodiment.

FIGS. 15(a) and 15(b) are cross-sectional views showing procedures for manufacturing a nonvolatile semiconductor memory device according to the second embodiment.

FIG. 16 is a diagram showing the write and erase characteristics of memory cells manufactured by the manufacturing methods according to the first and second embodiments.

FIG. 17 is a diagram showing the write and erase characteristics in a case where the voltage of a memory cell manufactured by the manufacturing method according to the second embodiment is varied.

FIG. 18 is a diagram showing the write and erase characteristics in a case where the voltage of a memory cell manufactured by the manufacturing method according to the first embodiment is varied.

FIG. 19 is a diagram showing the charge retention characteristics of memory cells manufactured by the manufacturing methods according to the first and second embodiments.

FIGS. 20(a) through 20(f) are cross-sectional views showing procedures for manufacturing a nonvolatile semiconductor memory device according to a third embodiment.

FIGS. 21(a) through 21(d) are cross-sectional views showing procedures for manufacturing a nonvolatile semiconductor memory device according to the third embodiment.

FIGS. 22(a) through 22(d) are cross-sectional views showing procedures for manufacturing a nonvolatile semiconductor memory device according to the third embodiment.

FIGS. 23(a) and 23(b) are cross-sectional views showing procedures for manufacturing a nonvolatile semiconductor memory device according to the third embodiment.

FIG. 24 is a diagram showing the write and erase characteristics of memory cells manufactured by the manufacturing methods according to the second and third embodiments.

FIGS. 25(a) and 25(b) are diagrams for explaining the Coulomb blockage effect in the tunnel insulating film formed by the manufacturing method according to the third embodiment.

FIG. 26 is a diagram showing the charge retention characteristics of the memory cells manufactured by the manufacturing methods according to the second and third embodiments.

FIG. 27 is a cross-sectional view showing procedures for manufacturing a nonvolatile semiconductor memory device according to a fourth embodiment.

FIG. 28 is a cross-sectional view showing procedures for manufacturing a nonvolatile semiconductor memory device according to the fourth embodiment.

FIG. 29 is a cross-sectional view showing procedures for manufacturing a nonvolatile semiconductor memory device according to the fourth embodiment.

FIG. 30 is a diagram showing the write and erase characteristics of memory cells manufactured by the manufacturing methods according to the third and fourth embodiments.

### DETAILED DESCRIPTION

A method of manufacturing a nonvolatile semiconductor memory device according to an embodiment includes: forming a first insulating film on a semiconductor substrate; forming a charge trapping film on the first insulating film, the forming of the charge trapping film including; forming a first nitride layer on the first insulating film at a heat treatment temperature of 550° C. or higher, forming a first oxynitride layer on the first nitride layer by oxidizing a surface of the first nitride layer, and forming a second nitride layer on the first oxynitride layer; forming a second insulating film on the charge trapping film; and forming a control gate on the second insulating film.

First, before describing the embodiments of the present invention, the course of events for achieving the present invention will be described below.

As described above, where future flash memories are expected to have multilayer structures or three-dimensional structures, and a technique for scaling the bit cost per volume needs to be developed, it is difficult to prevent degradation of retention characteristics due to miniaturization by reducing physical film thicknesses. In view of this, the inventors came to the conclusion that some measures need to be taken to improve the retention characteristics of charge storage films (hereinafter also referred to as charge trapping films). Specifically, the inventors invented the following two methods.

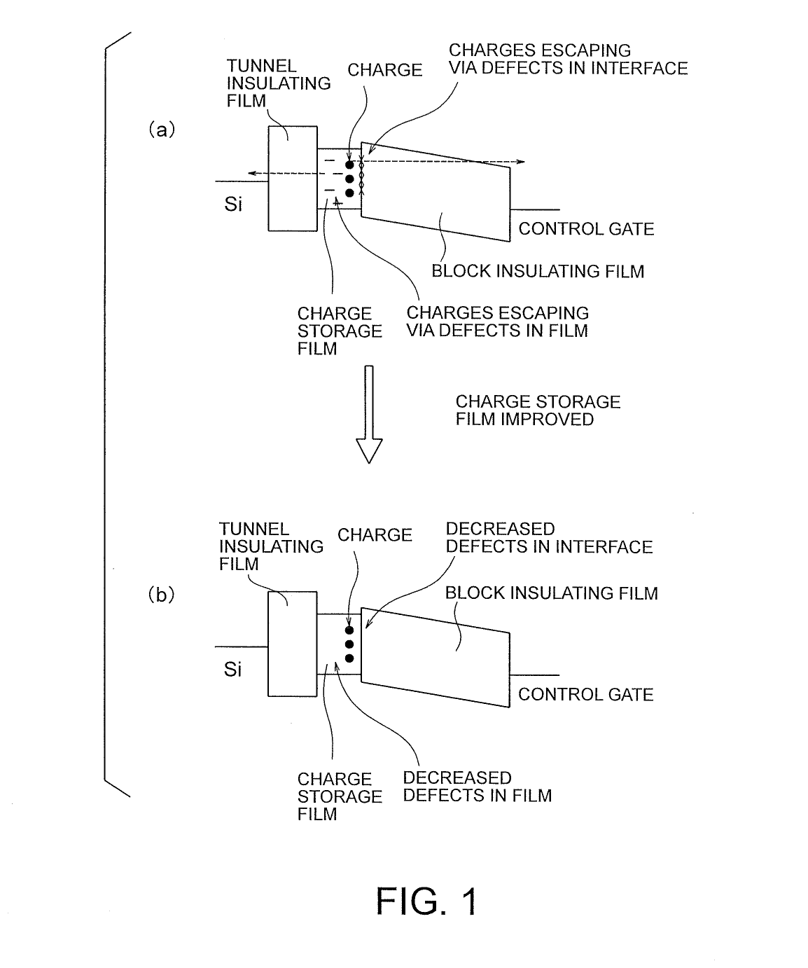

Referring to FIGS. 1(a) and 1(b), a first method is described. Retention characteristics are degraded where charges escape via defects formed in the interface between the charge storage film and the block insulating film, or charges escape via defects formed in the charge storage film and pass through a tunnel insulating film to reach the channel region, as shown in FIG. 1(a). Therefore, to reduce the defects in the interface between the charge storage film and the block insulating film, and reduce the defects in the charge storage film, as shown in FIG. 1(b), the inventors invented a technique for preventing charges from escaping from trap levels, by improving the insulation properties of the charge storage film while maintaining trap levels in the charge storage film.

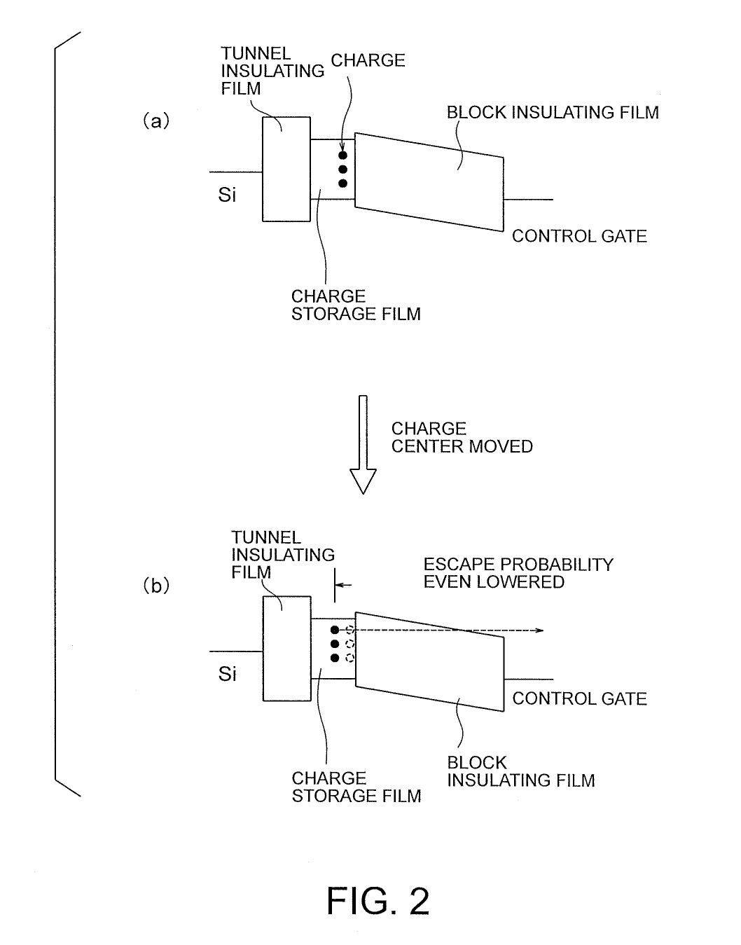

Referring now to FIGS. 2(a) and 2(b), a second method is described. Retention characteristics are degraded where the center of charges (hereinafter also referred to as the charge center) stored in the charge storage film is close to the interface between the charge storage film and the tunnel insulating film, or is close to the interface between the charge storage film and the block insulating film, as shown in FIG. 2(a). Therefore, the inventors invented a technique for increasing the physical film thickness required for charges to escape (or the barrier to be felt by charges) by moving the charge center away from the interface with the tunnel insulating film and the interface with the block insulating film, as shown in FIG. 2(b).

The following is a description of embodiments of the present invention, and the above first or second method is used in each of the following embodiments.

### First Embodiment

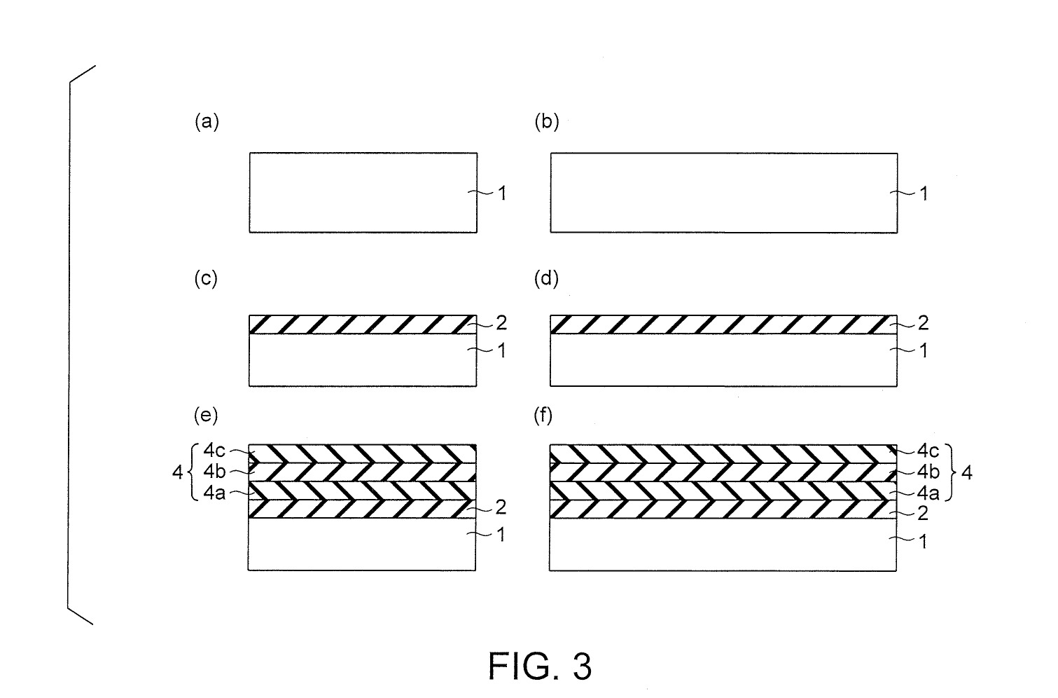

A method of manufacturing a nonvolatile semiconductor memory device according to a first embodiment of the present invention is described. The semiconductor memory device to be manufacturing by the manufacturing method according to this embodiment is a MONOS nonvolatile semiconductor memory, and includes memory cells. Referring to FIGS. 3(a) through 6(b), the memory manufacturing method according to this embodiment is described. FIGS. 3(a) through 6(b) are cross-sectional views illustrating manufacturing procedures of the manufacturing method according to this embodiment. FIGS. 3(a), 3(c), 3(e), 4(a), 4(c), 5(a), 5(c), and 6(a) show cross-sections perpendicular to those shown in FIGS. 3(b), 3(d), 3(f), 4(b), 4(d), 5(b), 5(d), and 6(b).

First, as shown in FIGS. 3(a) and 3(b), a silicon substrate 1 doped with a desired impurity is subjected to a diluted HF treatment, and the surface of the silicon substrate 1 is terminated by hydrogen. After that, the silicon substrate 1 is put into the chamber of a film forming apparatus. The chamber is then filled only with a gas (such as a nitrogen gas) that does not react with or etch the silicon during the manufacturing process. After that, the temperature of the silicon substrate 1 is increased to 700° C., so that hydrogen is completely eliminated from the silicon substrate 1.

The atmosphere in the chamber is then changed to a mixed gas atmosphere of N₂ of 30 Torr in partial pressure and O₂ of 3 Torr in partial pressure, for example, and the surface of the silicon substrate 1 is increased to and maintained at 1050° C. for 50 seconds. As a result, a silicon oxide film 2 to be the tunnel insulating film is formed on the silicon substrate 1, as shown in FIGS. 3(c) and 3(d).

With the use of dichlorosilane (SiH₂Cl₂) and NH₃, a 1-nm silicon nitride layer 4a is deposited on the silicon oxide film 2. At this point, the temperature of the silicon substrate 1 is preferably 550° C. or higher. In this embodiment, the temperature of the silicon substrate 1 is 700° C., for example. The atmosphere in the chamber is then changed to a mixed gas atmosphere of N₂ of 30 Torr in partial pressure and O₂ of 0.03 Torr in partial pressure, for example, and the surface of the silicon substrate 1 is adjusted to and maintained at 950° C. for 10 seconds. As a result, the surface of the silicon nitride layer 4a is oxidized to generate interstitial silicon, and a silicon oxynitride layer 4b is formed as shown in FIG. 3(e). At this point, the silicon nitride layer 4a is a layer continuing in the in-plane direction (a direction parallel to the upper surface of the silicon nitride layer 4a). The silicon nitride layer 4a has three-coordinate bonds, and also has a structure in which at least one of the second-neighbor atoms of nitrogen is a nitrogen atom. In this specification, three-coordinate bonds mean that three silicon atoms are bonded to one nitrogen atom. With the use of dichlorosilane and NH₃, a 1-nm silicon nitride layer 4c is then deposited on the silicon oxynitride layer 4b. At this point, the temperature of the silicon substrate 1 is preferably 550° C. or higher. In this embodiment, the temperature of the silicon substrate 1 is 630° C., for example. As a result, a charge trapping film 4 that is a stacked structure consisting of the silicon nitride layer 4a, the silicon oxynitride layer 4b, and the silicon nitride layer 4c is formed. Like the silicon nitride layer 4a, the silicon nitride layer 4c is also formed at a temperature of 550° C. or higher. Accordingly, the silicon nitride layer 4c becomes a high-quality silicon nitride layer that continues in the in-plane direction.

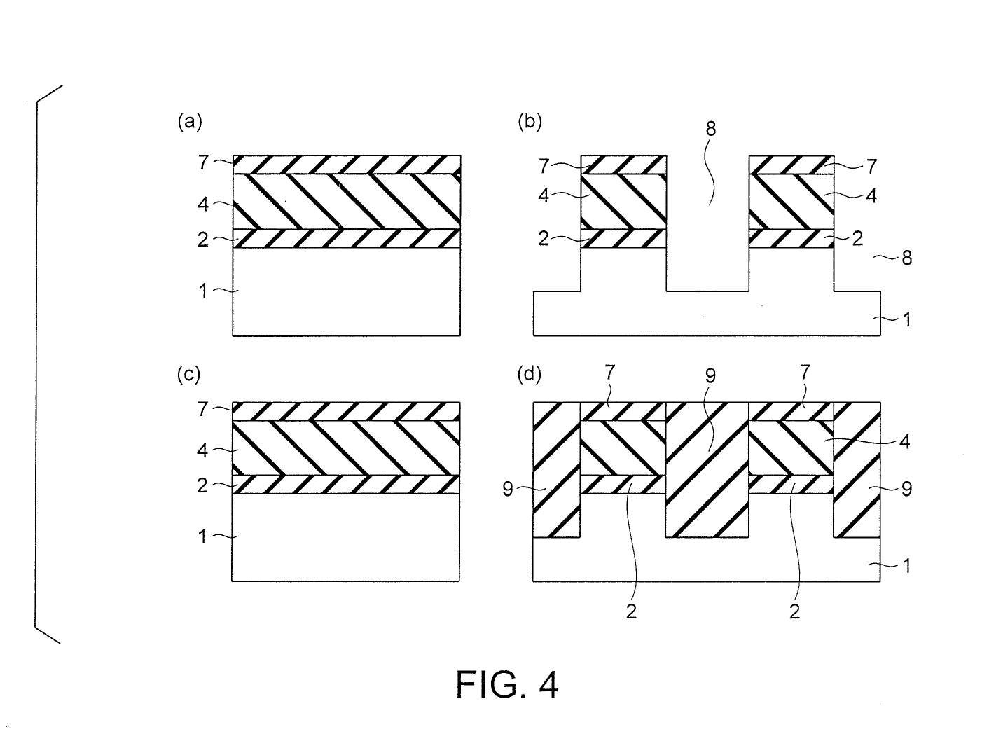

A mask material 7 for the device separating process is then deposited by CVD (Chemical Vapor Deposition) (FIGS. 4(a) and 4(b)). After that, etching is performed sequentially on the mask material 7, the charge trapping film 4, and the tunnel insulating film 2 by RIE (Reactive Ion Etching) using a resist mask (not shown), to partially expose the upper surface of the silicon substrate 1. Etching is further performed on the exposed regions of the silicon substrate 1, to form device isolating grooves 8 of 100 nm in depth, as shown in FIG. 4(b). After that, the resist mask is removed.

A silicon oxide film 9 for device isolation is then deposited on the entire surface, and the device isolating grooves 8 are completely filled. After that, the silicon oxide film 9 on the surface portions is removed by CMP (Chemical Mechanical Polishing), so that the surface of the silicon oxide film 9 is flattened. At this point, the mask material 7 is exposed (FIGS. 4(c) and 4(d)).

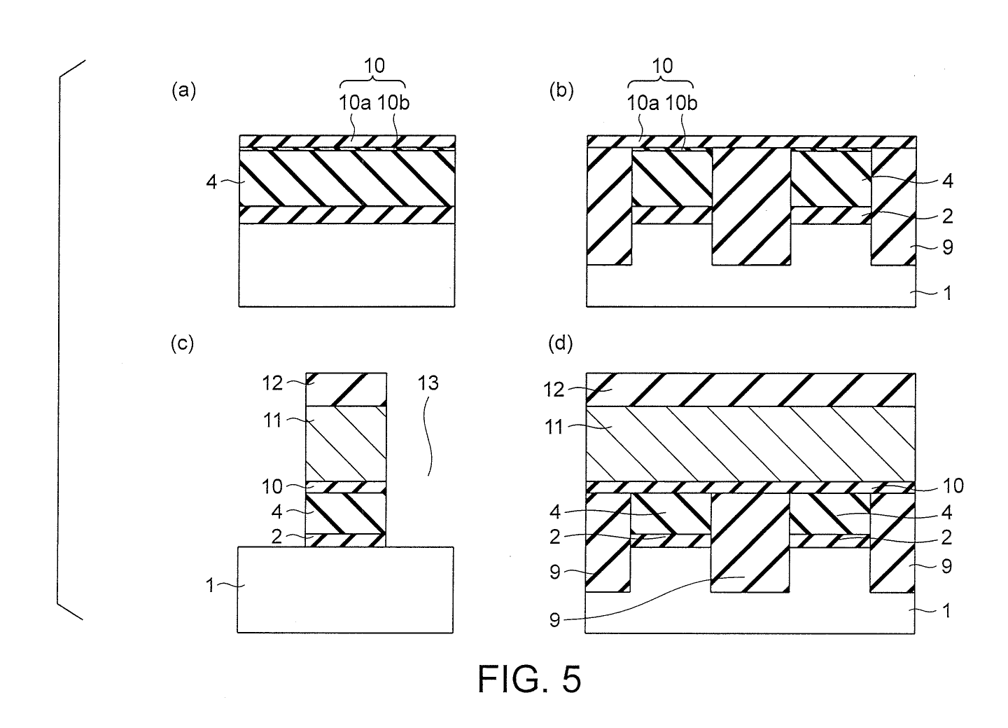

After the exposed mask material 7 is selectively removed by etching, the exposed faces of the silicon oxide film 9 are removed by etching with a diluted hydrofluoric acid solution. After that, an alumina layer 10a of 15 nm in thickness is deposited on the entire surface by ALD (Atomic Layer Deposition). At this point, the silicon nitride layer 4c that is the uppermost layer of the charge trapping film 4 and is in contact with the alumina layer is oxidized by the oxidizing agent used in the film formation by ALD, and an extremely thin silicon oxynitride layer 10b is formed. That is, a 16-nm thick block insulating film 10 that has a two-layer structure consisting of the silicon oxynitride layer 10b and the alumina layer 10a is formed (FIGS. 5(a) and 5(b)).

A polycrystalline silicon layer and a tungsten silicide layer to be the control gate are then sequentially deposited by CVD, and a 100-nm thick conductive film 11 that has a two-layer structure consisting of the polycrystalline silicon layer and the tungsten silicide layer is formed as the control gate. Further, a mask material 12 for RIE is deposited by CVD. After that, etching is performed sequentially on the mask material 12, the conductive film 11, the block insulating film 10, the charge trapping film 4, and the tunnel insulating film 2 by RIE using a resist mask (not shown), to form grooves 13 in the word-line direction (FIGS. 5(c) and 5(d)). In this manner, the shapes of the charge trapping film 4 and the control gate 11 are determined.

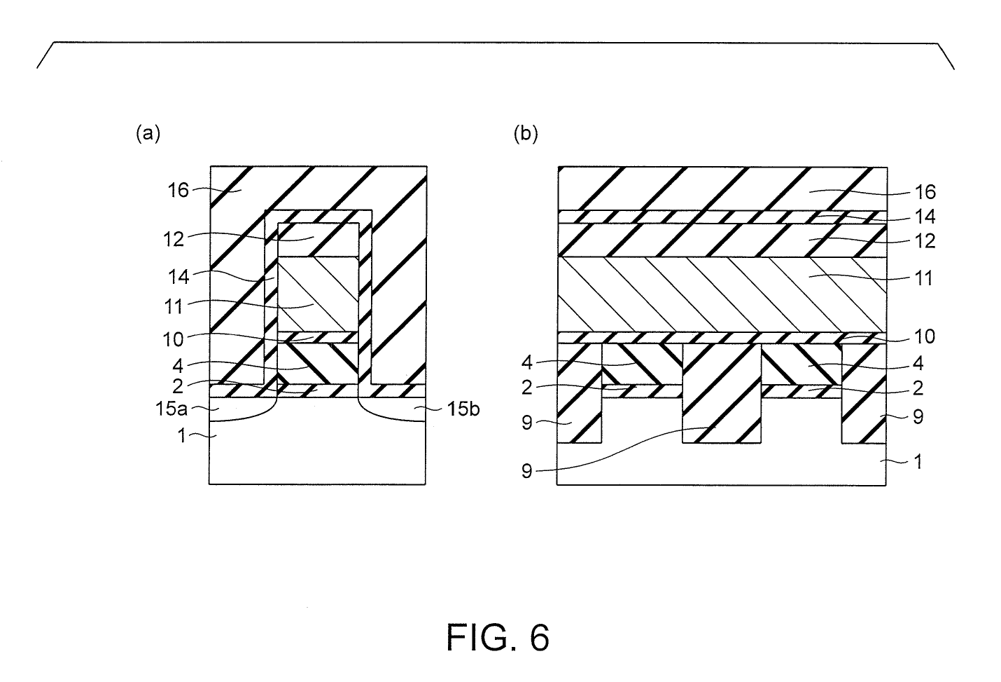

Lastly, a silicon oxide film 14 called an electrode sidewall oxide film is formed by a thermal oxidation technique on the exposed faces of the mask material 12, the control gate 11, the block insulating film 10, the charge trapping film 4, and the tunnel insulating film 2 (FIGS. 6(a) and 6(b)). After that, source/drain regions 15a and 15b are formed by using an ion implantation technique, and an interlayer insulating film 16 is further formed to cover the entire surface by CVD (FIGS. 6(a) and 6(b)). An interconnect layer and the like are then formed by a known technique, to complete the nonvolatile semiconductor memory.

As a first comparative example of this embodiment, a capacitor having a MONOS structure is also formed. In this capacitor, the block insulating film is a silicon-rich silicon nitride film (a silicon nitride film having Si/N higher than ¾) that has the same EOT (Equivalent Oxide Thickness) and the same trapped charge density as those of the block insulating film manufactured by the manufacturing method according to this embodiment. The silicon-rich silicon nitride film is formed by adjusting the supply ratio between dichlorosilane and NH₃. It should be noted that a capacitor having a MONOS structure is a capacitor in which a three-layer structure formed by stacking a tunnel insulating film, a charge trapping film, and a block insulating film in this order is used as a dielectric body, a silicon layer having impurities introduced thereinto is used as the lower electrode, and the control gate is used as the upper electrode.

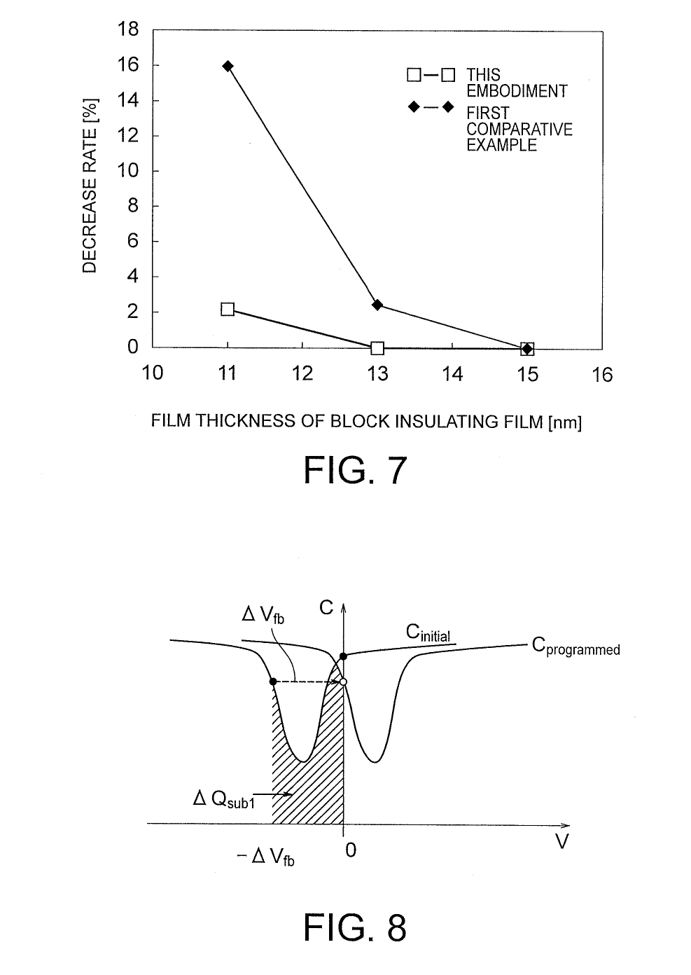

FIG. 7 shows the data retention characteristics of a capacitor having a MONOS structure manufactured by the manufacturing method according to this embodiment, and a capacitor having the MONOS structure of the first comparative example. The data retention characteristics are indicative of at what rate the amount of charges stored in the charge trapping film becomes lower after a predetermined period of time has passed since a predetermined amount of charges were stored in the charge trapping film where the film thickness of the block insulating film was varied. As can be seen from the characteristics shown in FIG. 7, in this embodiment, the shift amount ΔV_{fb} of the flat band voltage is smaller with respect to the reduction of the film thickness of the block insulating film, and the decrease in the amount of stored charges is smaller with respect to the reduction, compared with those in the first comparative example. This is because, in this embodiment, the high-quality silicon nitride layers 4a and 4c with high insulation properties, and charges are stored in the bandgaps of those silicon nitride layers 4a and 4c as the charge trapping film 4. In addition to that, the charge center exists in the vicinity of the silicon oxynitride layer 4b, and accordingly, the amount of charges escaping through the block insulating film side or the tunnel insulating film side becomes smaller as the charge center is located further away from the block insulating film or the tunnel insulating film.

The charge center is determined in the following manner. When a gate voltage is applied to a MONOS capacitor, charges are injected into the charge trapping film, and the flat band voltage V_{fb} shifts accordingly. Where ΔV_{fb} represents the shift amount at this point, ΔQₜᵣₐₚ represents the surface density of the charges newly trapped as a result of the application of the gate voltage, Z_{eff} represents the value of the EOT indicating the charge center position measured from the interface on the gate side, and ∈ₒₓ represents the permittivity of the SiO₂ film, the following equation is established:

ΔV_{fb}=−ΔQₜᵣₐₚ×Z_{eff}/∈ox

The charge center Z_{eff} can be measured by evaluating ΔV_{fb} and ΔQₜᵣₐₚ independently of each other. Where Cᵢₙᵢₜᵢₐₗ represents the CV characteristics of the MONOS capacitor prior to the application of the gate voltage, Qᵢₙⱼ represents the amount of charges to be injected into the MONOS capacitor, and ΔQ_{sub} represents the variation in the CV characteristics caused by the injection of the amount of charges, the charge center Z_{eff} can be expressed as follows:

$$\begin{matrix}{Z}_{eff} = - {ɛ}_{ox} \times Δ {V}_{fb} / ( {Q}_{inj} - Δ {Q}_{sub} ) \\ = - {ɛ}_{ox} \times Δ {V}_{fb} / ( {Q}_{inj} + \int {C}_{initial} d V )\end{matrix}$$

Here, the integral range of the CV characteristics Cᵢₙᵢₜᵢₐₗ is from −ΔV_{fb} to 0 V (see FIG. 8).

Since the manufacturing method according to this embodiment has the above features, the oxygen distribution in the charge trapping film is characteristic. In view of this, the first silicon nitride layer (equivalent to the silicon nitride layer 4a of this embodiment) is formed as the charge trapping film, and the block insulating film is then formed in a second comparative example. In this embodiment, on the other hand, after the high-quality silicon nitride layer 4a is formed, the surface of the silicon nitride layer 4a is oxidized to form the silicon oxynitride layer 4b on the surface of the silicon nitride layer 4a, and the silicon nitride layer 4c is formed on the silicon oxynitride layer 4b. In this manner, the charge trapping film 4 having the three-layer structure is formed, and the block insulating film is formed on the charge trapping film 4.

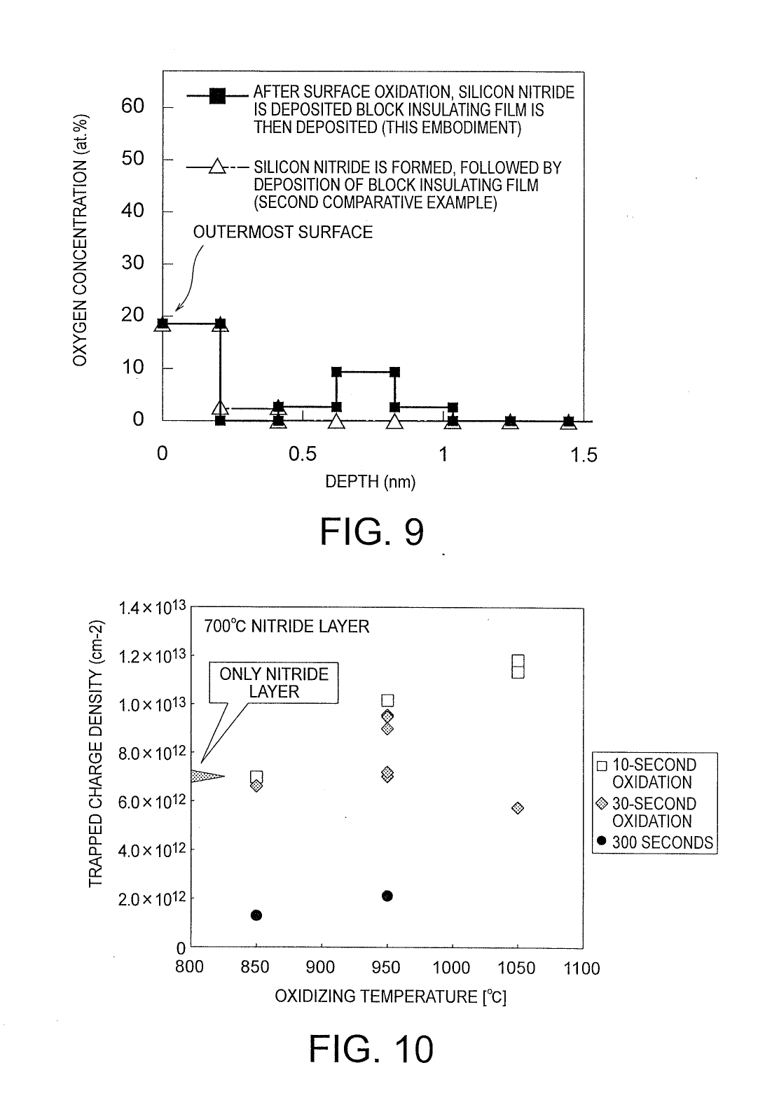

FIG. 9 shows the oxygen concentration distributions in the respective charge trapping films, which ware analyzed from the surface sides of the respective charge trapping films formed according to this embodiment and the second comparative example. In FIG. 9, the layer thickness of each of the silicon nitride layers in contact with the respective block insulating films, which are the silicon nitride layer in the second comparative example and the silicon nitride layer 4c in this embodiment, is 0.5 nm. As can be seen from FIG. 9, in the second comparative example, there is an oxygen peak only in the surface of the silicon nitride layer 4. In this embodiment, on the other hand, after the formation of the silicon nitride layer 4a, the surface is oxidized to form the silicon oxynitride layer 4b. After that, the silicon nitride layer 4c is formed, and the block insulating film is formed. In this embodiment, there is an oxygen peak not only in the surface of the charge trapping film but also in the charge trapping film. This indicates that the silicon oxynitride layer 4b formed by oxidizing the silicon nitride layer 4a remains even after the formation of the silicon nitride layer 4c. This aspect is one of the features of this embodiment.

The temperature for forming the silicon nitride layer 4a is preferably a temperature at which the silicon nitride layer 4a has three-coordinate bonds, and two or more nitrogen atoms exist as the second-neighbor atoms of nitrogen. Therefore, the temperature is preferably 550° C. or higher. Furthermore, to oxidize the silicon nitride layer 4a, the temperature is preferably 950° C. or higher, and the oxidation period is preferably 10 seconds or shorter. These are apparent from the experiment results described below.

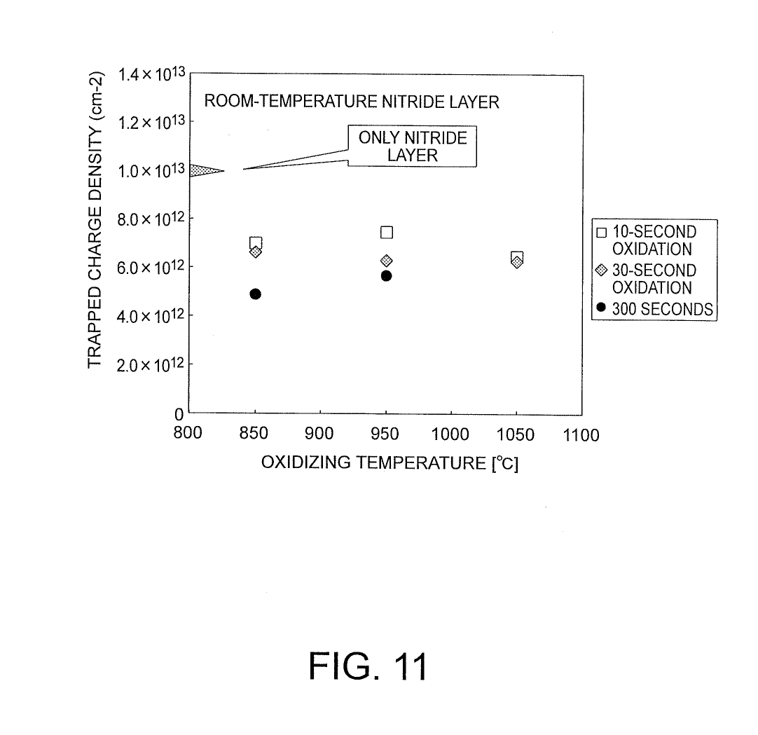

FIG. 10 shows the results of examinations carried out on the oxidizing temperature dependence of the trapped charge density in a silicon nitride layer where the period of time for oxidation to form a silicon oxynitride layer on the surface of the silicon nitride layer formed at 700° C. was varied from 10 seconds to 30 seconds to 300 seconds. FIG. 11 shows the results of examinations carried out on the oxidizing temperature dependence of the trapped charge density in a silicon nitride layer where the period of time for oxidation to form a silicon oxynitride layer on the surface of the silicon nitride layer formed at room temperature was varied from 10 seconds to 30 seconds to 300 seconds.

As can be seen from FIG. 10, the trapped charge density becomes higher, as the nitriding temperature is made higher, and the oxidizing process is performed at a higher temperature in a shorter period of time. This is because, if the surface of the silicon nitride layer is oxidized when the nitriding temperature is high and the silicon nitride layer has high quality, oxygen functions to destroy the Si—N bonds, and the interstitial Si increases in a case where the period of time for the oxidation is short. In a case where the period of time for the oxidation is long, on the other hand, the generated defects are terminated by oxygen, and the trapped charge density becomes lower accordingly.

Meanwhile, as shown in FIG. 11, there exist a large number of defects in the silicon nitride layer formed at a low temperature (room temperature). Therefore, the oxygen in the oxidizing process functions to correct defects even in the initial stage. Accordingly, the defect generation due to the oxidation does not easily occur, and the charge trapping film cannot be expected to function properly. It should be noted that, to reduce the variation in the production process, the period of time for the oxidation is preferably one second or longer.

As described so far, according to this embodiment, degradation of retention characteristics can be prevented as much as possible even if miniaturization is performed.

### Second Embodiment

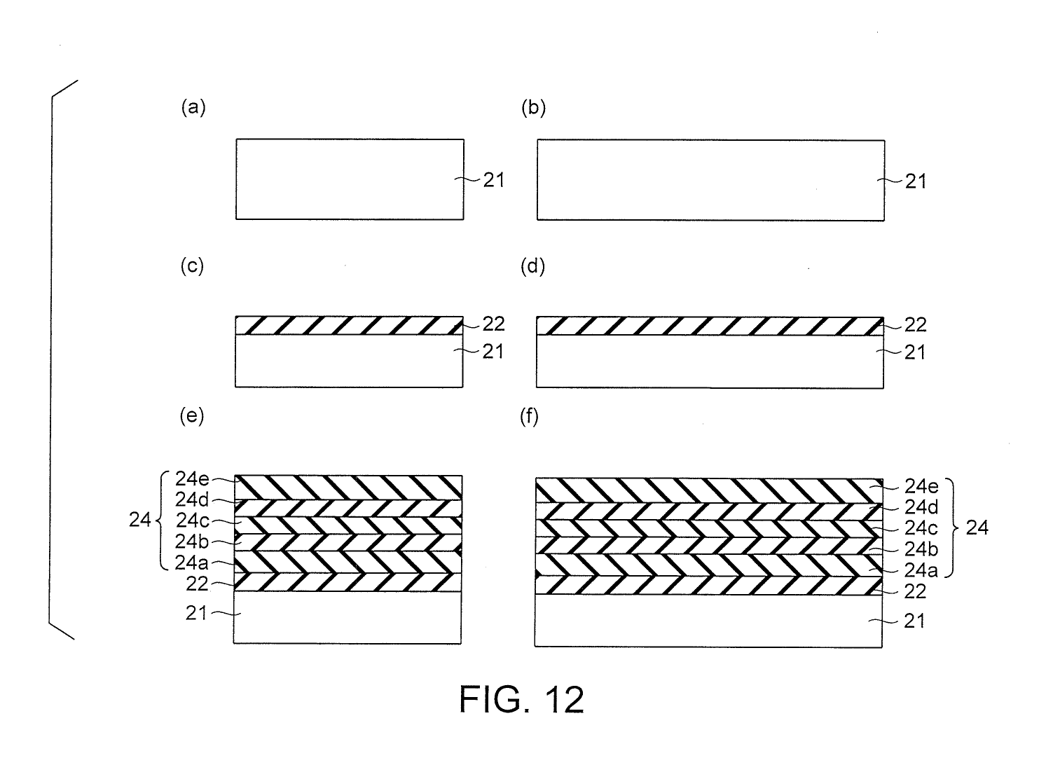

Next, a method of manufacturing a nonvolatile semiconductor memory device according to a second embodiment of the present invention is described. The nonvolatile semiconductor memory device to be manufacturing by the manufacturing method according to this embodiment is a MONOS nonvolatile memory, and includes memory cells. Referring to FIGS. 12(a) through 15(b), the memory manufacturing method according to this embodiment is described. FIGS. 12(a) through 15(b) are cross-sectional views illustrating manufacturing procedures of the manufacturing method according to this embodiment. FIGS. 12(a), 12(c), 12(e), 13(a), 13(c), 14(a), 14(c), and 15(a) show cross-sections perpendicular to those shown in FIGS. 12(b), 12(d), 12(f), 13(b), 13(d), 14(b), 14(d), and 15(b).

First, as shown in FIGS. 12(a) and 12(b), a silicon substrate 21 doped with a desired impurity is subjected to a diluted HF treatment, and the surface of the silicon substrate 21 is terminated by hydrogen. After that, the silicon substrate 21 is put into the chamber of a film forming apparatus. The chamber is then filled only with a gas (such as a nitrogen gas) that does not react with or etch the silicon during the manufacturing process. After that, the temperature of the silicon substrate 21 is increased to 700° C., so that hydrogen is completely eliminated from the silicon substrate 21.

The atmosphere in the chamber is then changed to a mixed gas atmosphere of N₂ of 30 Torr in partial pressure and O₂ of 3 Torr in partial pressure, for example, and the surface of the silicon substrate 21 is increased to and maintained at 1050° C. for 50 seconds. As a result, a silicon oxide film 22 to be the tunnel insulating film is formed on the silicon substrate 21, as shown in FIGS. 12(c) and 12(d).

With the use of dichlorosilane and NH₃, a 1-nm silicon nitride layer 24a is then deposited on the silicon oxide film 22, as shown in FIGS. 12(e) and 12(f). At this point, the temperature of the silicon substrate 21 is preferably 550° C. or higher. In this embodiment, the temperature of the silicon substrate 21 is 700° C., for example. The atmosphere in the chamber is then changed to a mixed gas atmosphere of N₂ of 30 Torr in partial pressure and O₂ of 0.03 Torr in partial pressure, for example, and the surface of the silicon substrate 21 is adjusted to and maintained at 950° C. for 10 seconds. As a result, the surface of the silicon nitride layer 24a is oxidized to generate interstitial Si, and a silicon oxynitride layer 24b is formed as shown in FIGS. 12(e) and 12(f). At this point, the silicon nitride layer 24a is a layer continuing in the in-plane direction, and has three-coordinate bonds. Also, the silicon nitride layer 24a has a structure in which at least one of the second-neighbor atoms of nitrogen is a nitrogen atom. With the use of dichlorosilane and NH₃, a 1-nm silicon nitride layer 24c is then deposited on the silicon oxynitride layer 24b. At this point, the temperature of the silicon substrate 21 is preferably 550° C. or higher. In this embodiment, the temperature of the silicon substrate 21 is 700° C., for example. The atmosphere in the chamber remains a mixed gas atmosphere of N₂ of 30 Torr in partial pressure and O₂ of 0.03 Torr in partial pressure, for example, and the surface of the silicon substrate 21 is adjusted to and maintained at 950° C. for 10 seconds. As a result, the surface of the silicon nitride layer 24c is oxidized to generate interstitial Si, and a silicon oxynitride layer 24d is formed. At this point, the silicon nitride layer 24c is a layer continuing in the in-plane direction, and has three-coordinate bonds. Also, the silicon nitride layer 24c has a structure in which at least one of the second-neighbor atoms of nitrogen is a nitrogen atom. With the use of dichlorosilane and NH₃, a 1-nm silicon nitride layer 24e is then deposited on the silicon oxynitride layer 24d. At this point, the temperature of the silicon substrate 21 is preferably 550° C. or higher. In this embodiment, the temperature of the silicon substrate 21 is 630° C., for example. As a result, a charge trapping film 24 that is a stacked structure consisting of the silicon nitride layer 24a, the silicon oxynitride layer 24b, the silicon nitride layer 24c, the silicon oxynitride layer 24d, and the silicon nitride layer 24e is formed (FIGS. 12(e) and 12(f)). Like the silicon nitride layers 24a and 24c, the silicon nitride layer 24e is also formed at a temperature of 550° C. or higher. Accordingly, the silicon nitride layer 24e becomes a high-quality silicon nitride layer that continues in the in-plane direction.

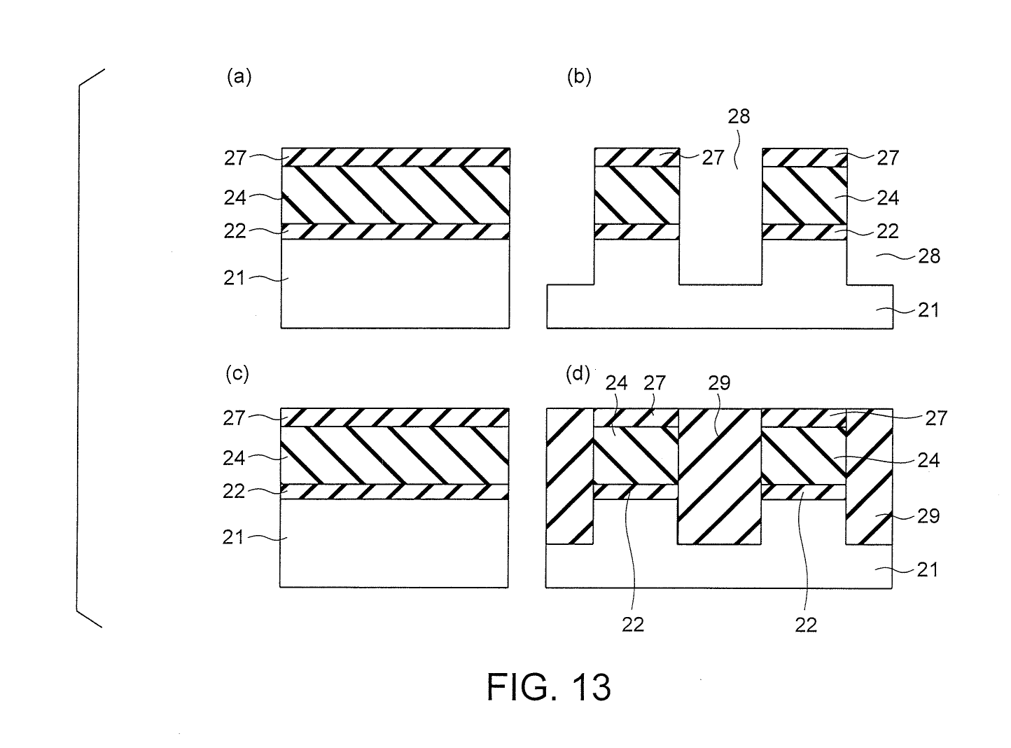

A mask material 27 for the device separating process is then deposited by CVD (FIGS. 13(a) and 13(b)). After that, etching is performed sequentially on the mask material 27, the charge trapping film 24, and the tunnel insulating film 22 by RIE using a resist mask (not shown), to partially expose the upper surface of the silicon substrate 21. Etching is further performed on the exposed regions of the silicon substrate 21, to form device isolating grooves 28 of 100 nm in depth, as shown in FIG. 13(b).

A silicon oxide film 29 for device isolation is then deposited on the entire surface, and the device isolating grooves 28 are completely filled. After that, the silicon oxide film 29 on the surface portions is removed by using CMP, so that the surface of the silicon oxide film 29 is flattened. At this point, the mask material 27 is exposed (FIGS. 13(c) and 13(d)).

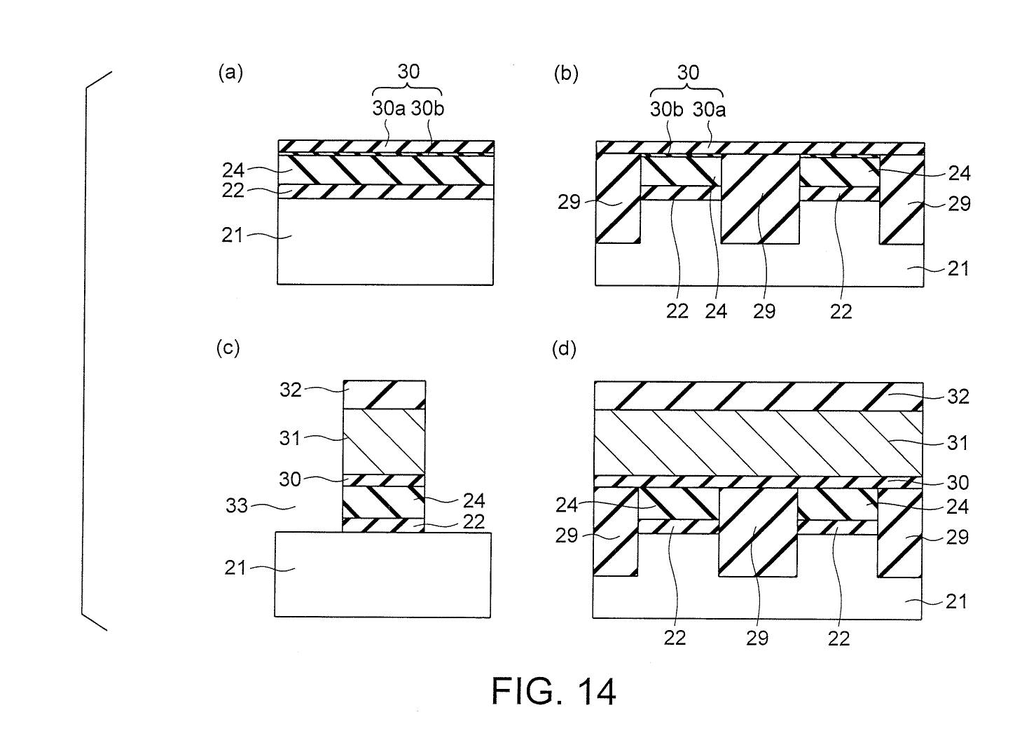

After the exposed mask material 27 is selectively removed by etching, the exposed faces of the silicon oxide film 29 are removed by etching with a diluted hydrofluoric acid solution. After that, an alumina layer 30a of 15 nm in thickness to be the block insulating film is deposited on the entire surface by ALD. At this point, the silicon nitride layer 24e that is the uppermost layer of the charge trapping film 24 and is in contact with the alumina layer 30a is oxidized by the oxidizing agent used in the film formation by ALD, and an extremely thin silicon oxynitride layer 30b is formed. That is, a 16-nm thick block insulating film 30 that has a two-layer structure consisting of the silicon oxynitride layer 30b and the alumina layer 30a is formed (FIGS. 14(a) and 14(b)).

A polycrystalline silicon layer and a tungsten silicide layer are then sequentially deposited by CVD, and a 100-nm thick conductive film 31 that has a two-layer structure consisting of the polycrystalline silicon layer and the tungsten silicide layer is formed as the control gate. Further, a mask material 32 for RIE is deposited by CVD. After that, etching is performed sequentially on the mask material 32, the conductive film 31, the block insulating film 30, the charge trapping film 24, and the tunnel insulating film 22 by RIE using a resist mask (not shown), to form grooves 33 in the word-line direction (FIGS. 14(c) and 14(d)). In this manner, the shapes of the charge trapping film 24 and the control gate 31 are determined.

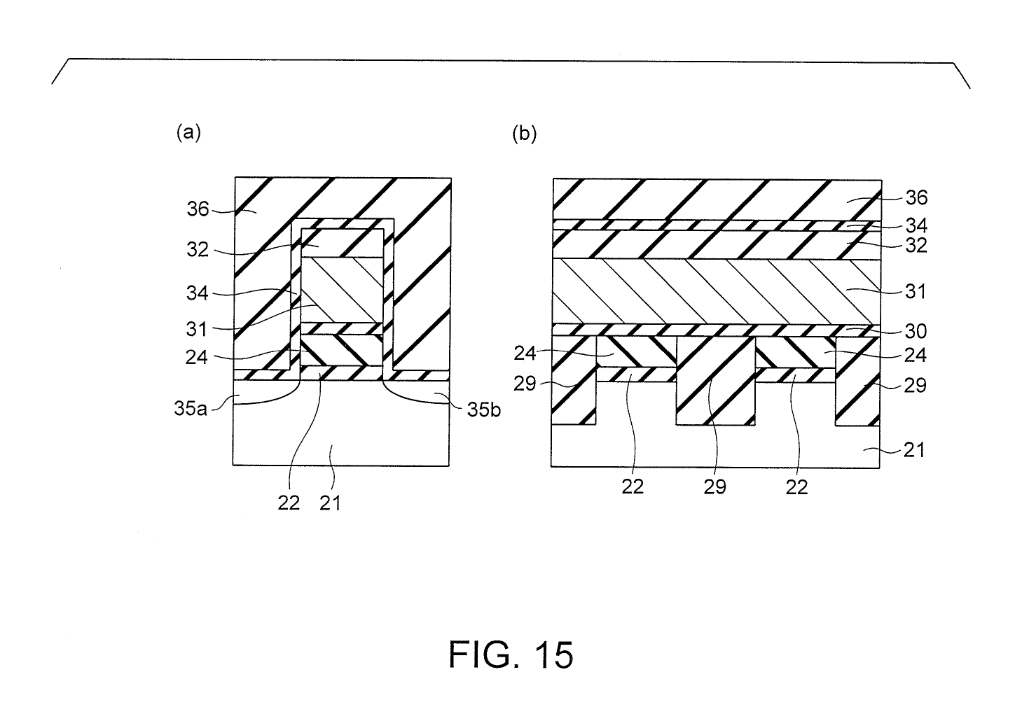

Lastly, a silicon oxide film 34 called an electrode sidewall oxide film is formed by a thermal oxidation technique on the exposed faces of the mask material 32, the control gate 31, the block insulating film 30, the charge trapping film 24, and the tunnel insulating film 22 (FIGS. 15(a) and 15(b)). After that, source/drain regions 35a and 35b are formed by using an ion implantation technique, and an interlayer insulating film 36 is further formed to cover the entire surface by CVD (FIGS. 15(a) and 15(b)). An interconnect layer and the like are then formed by a known technique, to complete the nonvolatile semiconductor memory.

The charge trapping film 24 of a memory cell manufactured by the manufacturing method according to this embodiment has a five-layer structure consisting of the silicon nitride layer 24a, the silicon oxynitride layer 24b, the silicon nitride layer 24c, the silicon oxynitride layer 24d, and the silicon nitride layer 24e. On the other hand, the charge trapping film 4 of a memory cell manufactured by the manufacturing method according to the first embodiment has a three-layer structure consisting of the silicon nitride layer 4a, the silicon oxynitride layer 4b, and the silicon nitride layer 4c. That is, by the manufacturing method according to the first embodiment, after a silicon nitride layer is formed on the tunnel insulating film, the oxidizing process and the nitride layer formation are performed once. By the manufacturing method according to the second embodiment, on the other hand, after a silicon nitride layer is formed on the tunnel insulating film, the oxidizing process and the nitride layer formation are repeated twice.

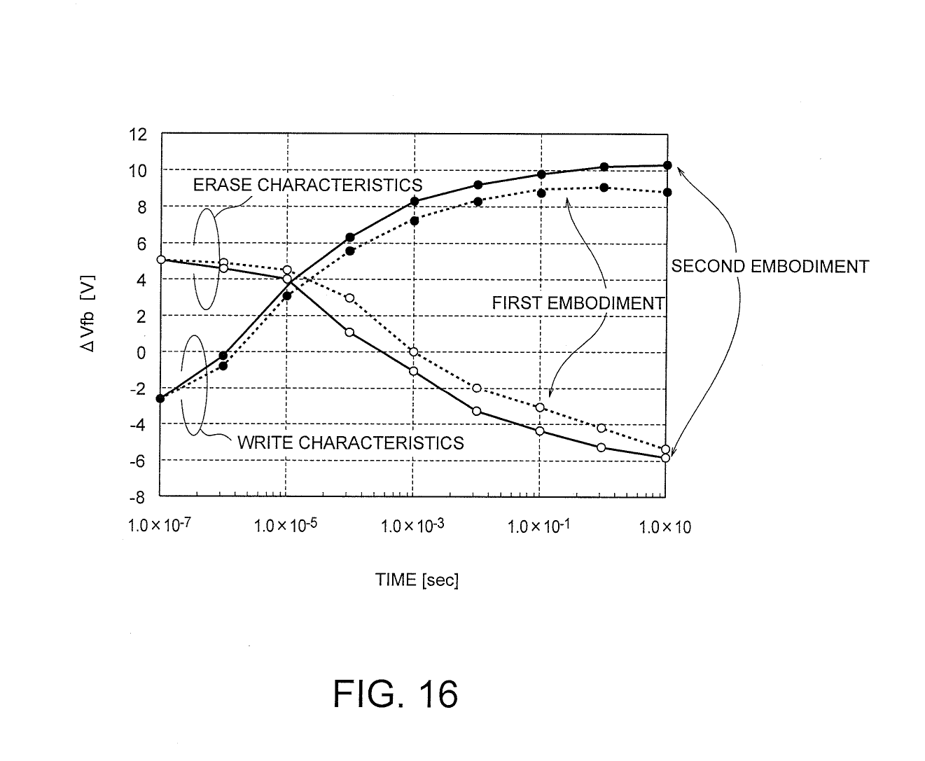

FIG. 16 shows the write and erase characteristics of a memory cell manufactured by the manufacturing method according to the second embodiment, and a memory cell manufactured by the manufacturing method according to the first embodiment. As can be seen from FIG. 16, the memory cell manufactured by the manufacturing method according to the second embodiment has improved write characteristics and improved erase characteristics, compared with those of the memory cell manufactured by the manufacturing method according to the first embodiment. This is because the volume of the charge trapping film increases, and the amount of trapped charges also increases, as the silicon nitride layer formation and the oxidizing process are repeated twice.

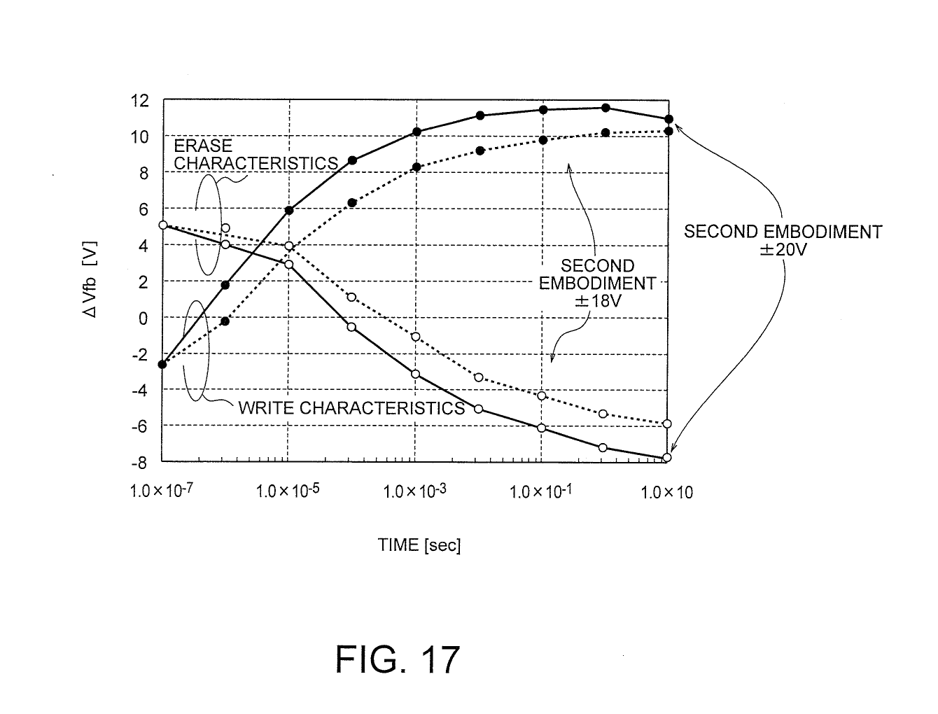

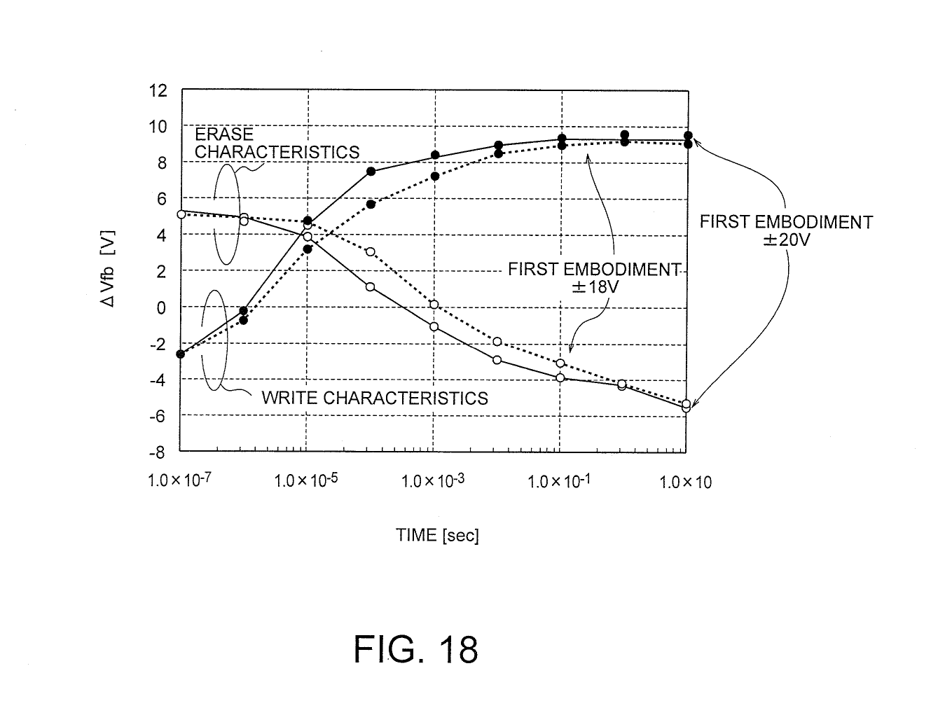

FIG. 17 shows variations of characteristics observed when writing and erasing were performed where the voltage to be applied to a memory cell manufactured by the manufacturing method according to the second embodiment was varied. FIG. 18 shows variations of characteristics observed when writing and erasing were performed where the voltage to be applied to a memory cell manufactured by the manufacturing method according to the first embodiment was varied. In both of the memory cells manufactured by the manufacturing methods of the two embodiments, +18 V and +20 V were applied between the control gate and the substrate at the time of writing, and −18 V and −20 V were applied between the control gate and the substrate at the time of erasing.

As can be seen from FIG. 18, in the memory cell manufactured by the manufacturing method according to the first embodiment, the shift amount ΔVfb of the flat band voltage in the writing and erasing on the high-voltage side reached saturation. By the manufacturing method according to the second embodiment, on the other hand, the silicon nitride layer formation and the oxidizing process are repeated twice, so as to desaturate the shift amount ΔVfb of the flat band voltage in the writing and erasing on the high-voltage side, as can be seen from FIG. 17. This is because the amount of trapped charges is larger than that in the first embodiment. In addition to that, since another charge trapping layer 24e is formed at a different distance from the channel, the shift amount ΔVfb in the depth direction as well as the amount of trapped charges can be controlled.

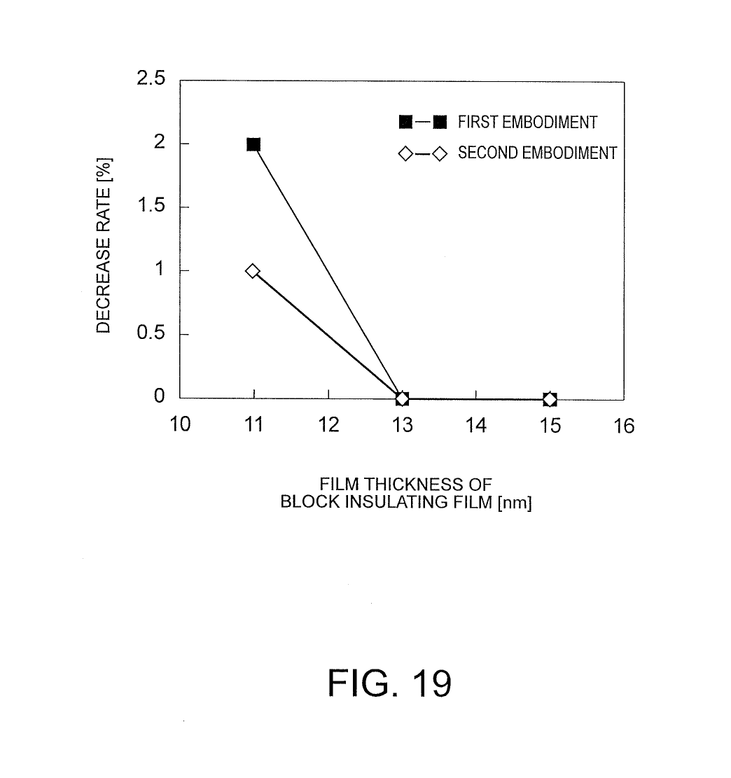

FIG. 19 shows the data retention characteristics of a memory cell manufactured by the manufacturing method according to the second embodiment, and a memory cell manufactured by the manufacturing method according to the first embodiment. The data retention characteristics are indicative of at what rate the amount of charges stored in the charge trapping film becomes lower after a predetermined period of time has passed since a predetermined amount of charges were stored in the charge trapping film where the film thickness of the block insulating film was varied. As can be seen from the characteristics shown in FIG. 19, the retention characteristics are improved by repeating the silicon nitride layer formation and the oxidizing process twice. This is because charges are stored in the bandgaps of the high-quality silicon nitride layers with higher insulation properties. In addition to that, the retention characteristics are improved, because the two high-quality silicon nitride layers 24c and 24e are interposed between the first silicon nitride layer 24a and the block insulating film 30. Furthermore, the retention characteristics are improved, because the amount of charges escaping through the block insulating film side becomes smaller as the charge center is located further away from the block insulating film.

As described so far, according to this embodiment, degradation of retention characteristics can be prevented as much as possible even if miniaturization is performed.

### Third Embodiment

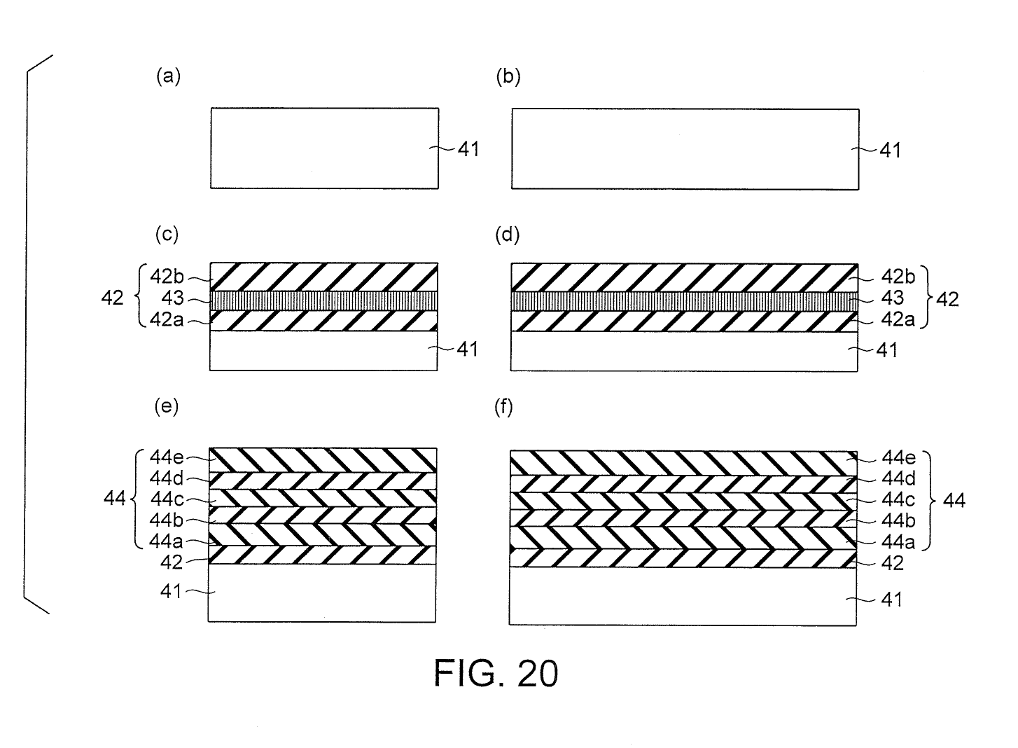

Next, a method of manufacturing a nonvolatile semiconductor memory device according to a third embodiment of the present invention is described. The nonvolatile semiconductor memory device to be manufactured by the manufacturing method according to this embodiment is a MONOS nonvolatile memory, and includes memory cells. Referring to FIGS. 20(a) through 23(b), the semiconductor memory manufacturing method according to this embodiment is described. FIGS. 20(a) through 23(b) are cross-sectional views illustrating manufacturing procedures of the manufacturing method according to this embodiment. FIGS. 20(a), 20(c), 20(e), 21(a), 21(c), 22(a), 22(c), and 23(a) show cross-sections perpendicular to those shown in FIGS. 20(b), 20(d), 20(f), 21(b), 21(d), 22(b), 22(d), and 23(b).

First, as shown in FIGS. 20(a) and 20(b), a silicon substrate 41 doped with a desired impurity is subjected to a diluted HF treatment, and the surface of the silicon substrate 41 is terminated by hydrogen. After that, the silicon substrate 41 is put into the chamber of a film forming apparatus. The chamber is then filled only with a gas (such as a nitrogen gas) that does not react with or etch the silicon during the manufacturing process. After that, the temperature of the silicon substrate 41 is increased to 700° C., so that hydrogen is completely eliminated from the silicon substrate 41.

The atmosphere in the chamber is then changed to a mixed gas atmosphere of N₂ of 30 Torr in partial pressure and O₂ of 3 Torr in partial pressure, for example, and the surface of the silicon substrate 41 is increased to and maintained at 1050° C. for 50 seconds. As a result, a silicon oxide layer 42a is formed on the silicon substrate 41, as shown in FIGS. 20(c) and 20(d). After that, a treatment using SH, which is a mixed solution of H₂O₂ and H₂SO₄, is performed on the surface of the silicon oxide layer 42a. With the use of disilane (Si₂H₆), a 2-nm thick amorphous Si layer is deposited on the silicon oxide layer 42a. The atmosphere in the chamber remains a mixed gas atmosphere of N₂ of 30 Torr in partial pressure and O₂ of 3 Torr in partial pressure, for example, and the surface of the silicon substrate 41 is adjusted to and maintained at 700° C. for 10 seconds. As a result, a silicon oxide layer 42b is formed on the amorphous silicon layer. The atmosphere in the chamber remains a mixed gas atmosphere of N₂ of 30 Torr in partial pressure and O₂ of 3 Torr in partial pressure, for example, and the surface of the silicon substrate 41 is adjusted to and maintained at 1000° C. for 15 minutes. As a result, the amorphous silicon layer is crystallized, and a microcrystalline layer 43 in which Si quantum dots are distributed at a high density is formed. In this manner, a tunnel insulating film 42 consisting of the silicon oxide layer 42a, the microcrystalline layer 43, and the silicon oxide layer 42b is formed.

With the use of dichlorosilane and NH₃, a 1-nm silicon nitride layer 44a is then deposited on the silicon oxide film 42ab, as shown in FIGS. 20(e) and 20(f). At this point, the temperature of the silicon substrate 41 is preferably 550° C. or higher. In this embodiment, the temperature of the silicon substrate 41 is 700° C., for example. The atmosphere in the chamber is then changed to a mixed gas atmosphere of N₂ of 30 Torr in partial pressure and O₂ of 0.03 Torr in partial pressure, and the surface of the silicon substrate 41 is adjusted to and maintained at 950° C. for 10 seconds. As a result, the surface of the silicon nitride layer 44a is oxidized to generate interstitial silicon, and a silicon oxynitride layer 44b is formed as shown in FIGS. 20(e) and 20(f). At this point, the silicon nitride layer 44a is a layer continuing in the in-plane direction, and has three-coordinate bonds. Also, the silicon nitride layer 44a has a structure in which at least one of the second-neighbor atoms of nitrogen is a nitrogen atom. With the use of dichlorosilane and NH₃, a 1-nm silicon nitride layer 44c is then deposited on the silicon oxynitride layer 44b. At this point, the temperature of the silicon substrate 41 is preferably 550° C. or higher. In this embodiment, the temperature of the silicon substrate 41 is 700° C., for example. The atmosphere in the chamber remains a mixed gas atmosphere of N₂ of 30 Torr in partial pressure and O₂ of 0.03 Torr in partial pressure, for example, and the surface of the silicon substrate 41 is adjusted to and maintained at 950° C. for 10 seconds. As a result, the surface of the silicon nitride layer 44c is oxidized to generate interstitial Si, and a silicon oxynitride layer 44d is formed. At this point, the silicon nitride layer 44c is a layer continuing in the in-plane direction, and has three-coordinate bonds. Also, the silicon nitride layer 44c has a structure in which at least one of the second-neighbor atoms of nitrogen is a nitrogen atom. With the use of dichlorosilane and NH₃, a 1-nm silicon nitride layer 44e is then deposited on the silicon oxynitride layer 44d. At this point, the temperature of the silicon substrate 41 is preferably 550° C. or higher. In this embodiment, the temperature of the silicon substrate 41 is 630° C., for example. As a result, a charge trapping film 44 that is a five-layer structure consisting of the silicon nitride layer 44a, the silicon oxynitride layer 44b, the silicon nitride layer 44c, the silicon oxynitride layer 44d, and the silicon nitride layer 44e is formed. Like the silicon nitride layers 44a and 44c, the silicon nitride layer 44e is also formed at a temperature of 550° C. or higher. Accordingly, the silicon nitride layer 44e becomes a high-quality silicon nitride layer that continues in the in-plane direction.

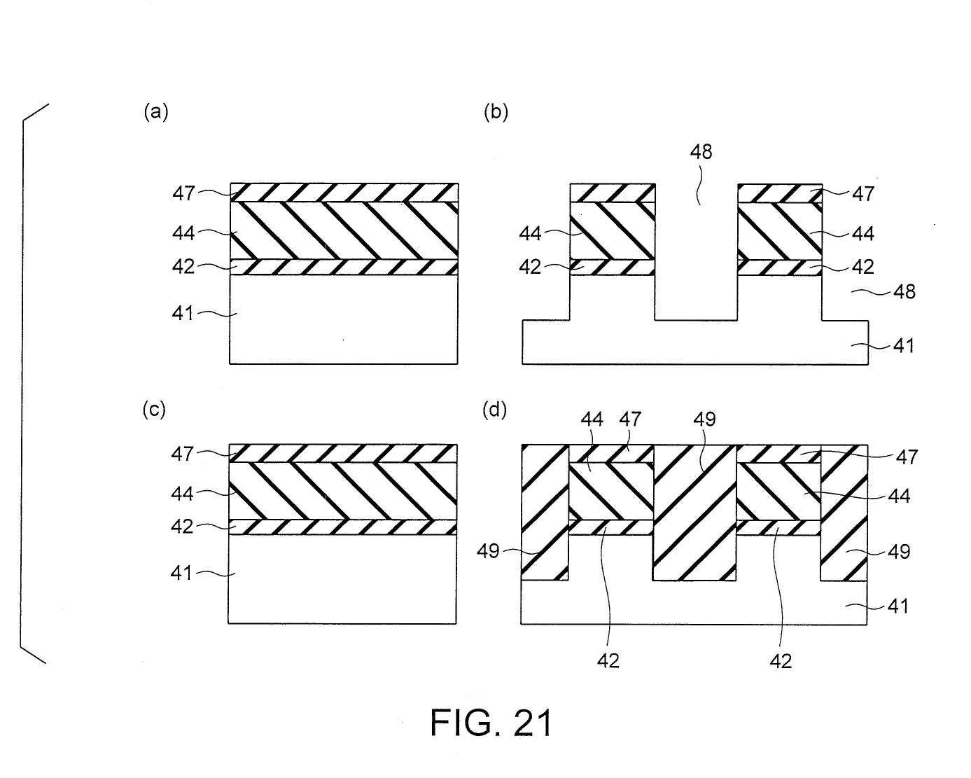

A mask material 47 for the device separating process is then deposited by CVD (FIGS. 21(a) and 21(b)). After that, etching is performed sequentially on the mask material 47, the charge trapping film 44, and the tunnel insulating film 42 by RIE using a resist mask (not shown), to partially expose the upper surface of the silicon substrate 41. Etching is further performed on the exposed regions of the silicon substrate 41, to form device isolating grooves 48 of 100 nm in depth, as shown in FIG. 21(b). After that, the resist mask is removed.

A silicon oxide film 49 for device isolation is then deposited on the entire surface, and the device isolating grooves 48 are completely filled. After that, the silicon oxide film 49 on the surface portions is removed by CMP, so that the surface of the silicon oxide film 49 is flattened. At this point, the upper faces of the mask material 47 are exposed (FIGS. 21(c) and 21(d)).

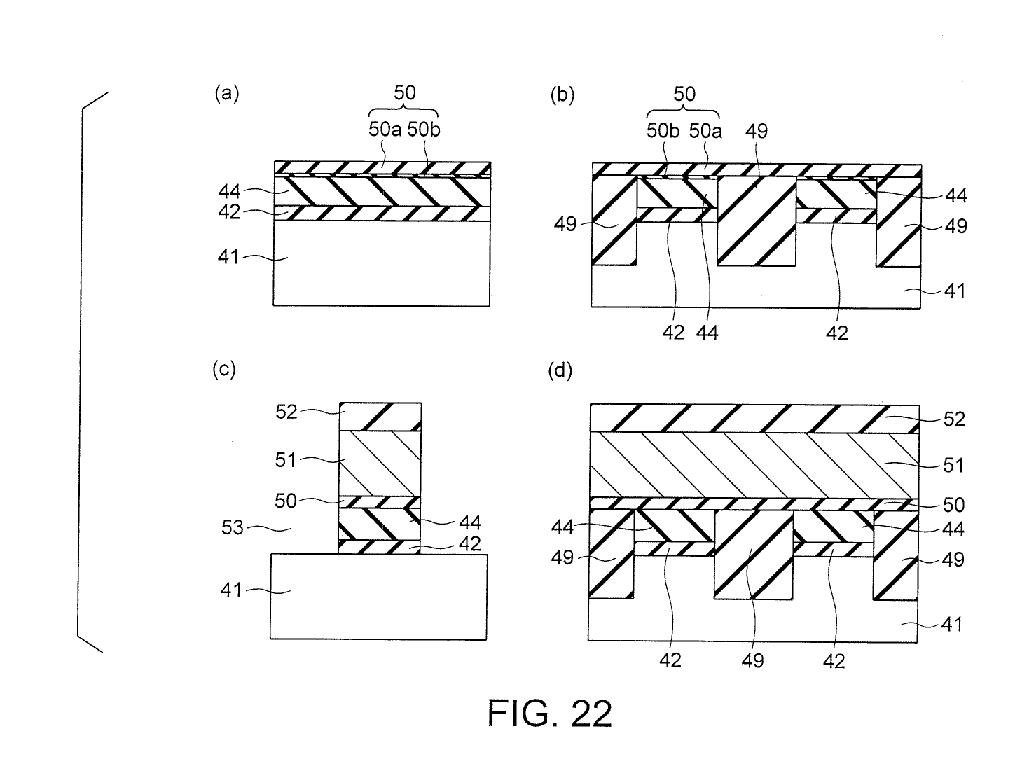

After the exposed mask material 47 is selectively removed by etching, the exposed faces of the silicon oxide film 49 are removed by etching with a diluted hydrofluoric acid solution. After that, an alumina layer 50a of 15 nm in thickness is deposited on the entire surface by ALD. At this point, the silicon nitride layer 44e that is the uppermost layer of the charge trapping film 44 is oxidized by the oxidizing agent used in the film formation by ALD, and an extremely thin silicon oxynitride layer 50b is formed. In this manner, a 16-nm thick block insulating film 50 that has a two-layer structure consisting of the silicon oxynitride layer 50b and the alumina layer 50a is formed (FIGS. 22(a) and 22(b)).

A polycrystalline silicon layer and a tungsten silicide layer to be the control gate are then sequentially deposited by CVD, and a 100-nm thick conductive film 51 that has a two-layer structure consisting of the polycrystalline silicon layer and the tungsten silicide layer is formed (FIGS. 22(c) and 22(d)). Further, a mask material 52 for RIE is deposited by CVD. After that, etching is performed sequentially on the mask material 52, the conductive film 51, the block insulating film 50, the charge trapping film 44, and the tunnel insulating film 42 by RIE using a resist mask (not shown), to form grooves 53 in the word-line direction (FIGS. 22(c) and 22(d)). In this manner, the shapes of the charge trapping film 44 and the control gate 51 are determined.

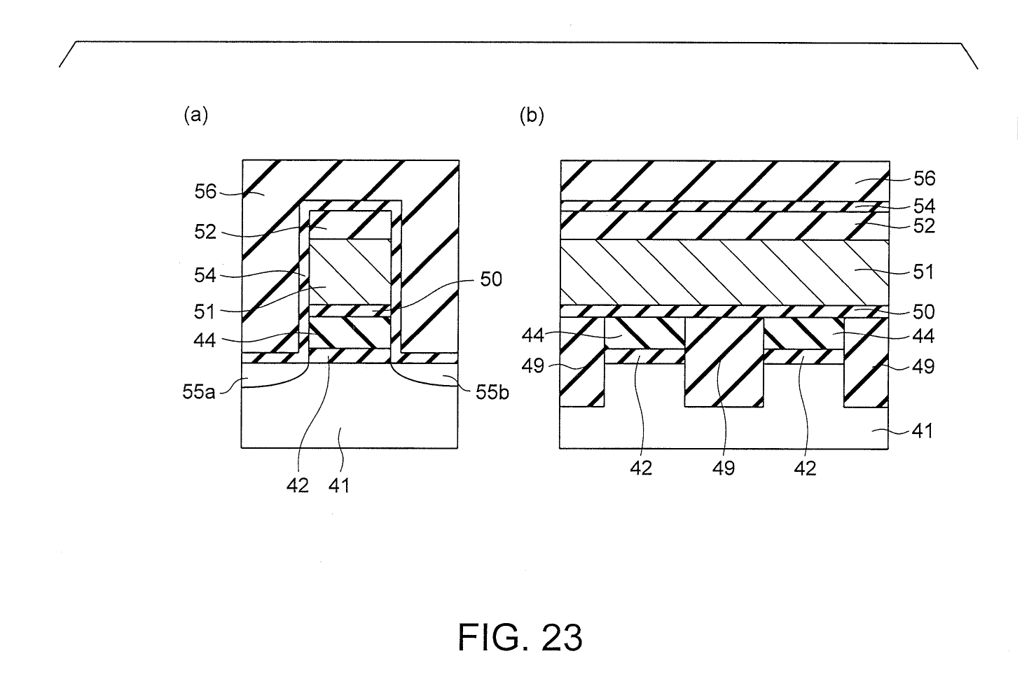

Lastly, a silicon oxide film 54 called an electrode sidewall oxide film is formed by a thermal oxidation technique on the exposed faces of the mask material 52, the control gate 51, the block insulating film 50, the charge trapping film 44, and the tunnel insulating film 42 (FIGS. 23(a) and 23(b)). After that, source/drain regions 55a and 55b are formed by using an ion implantation technique, and an interlayer insulating film 56 is further formed to cover the entire surface by CVD (FIGS. 23(a) and 23(b)). An interconnect layer and the like are then formed by a known technique, to complete the nonvolatile semiconductor memory cells.

A memory cell manufactured by the manufacturing method according to the third embodiment and a memory cell manufactured by the manufacturing method according to the second embodiment are the same in structure of the charge trapping film, but differ from each other in structure of the tunnel insulating film 42. That is, in the third embodiment, the tunnel insulating film 42 has a three-layer structure in which the microcrystalline layer 43 that is formed by crystallizing an amorphous silicon layer and has a high-density dot distribution is interposed between the silicon oxide layer 42a and the silicon oxide layer 42b. In the second embodiment, on the other hand, the tunnel insulating film 22 is a silicon oxide film.

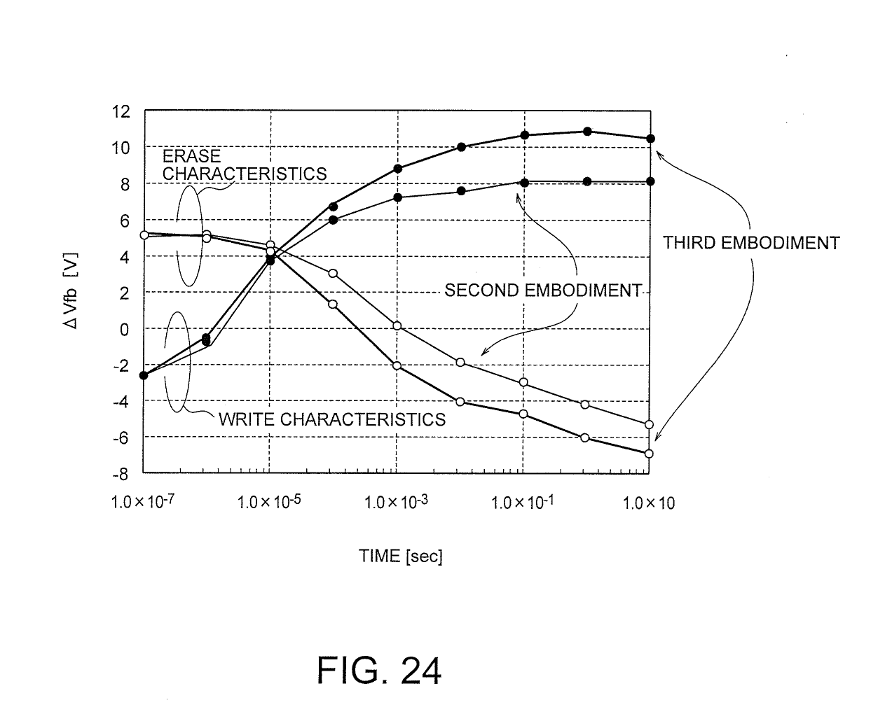

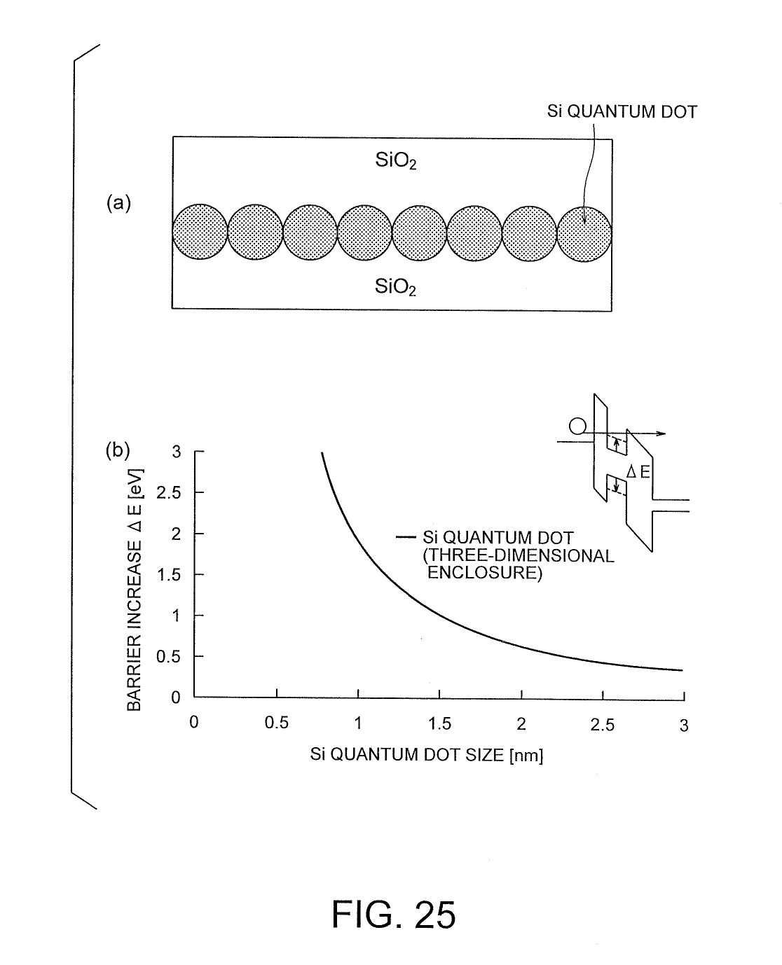

FIG. 24 shows the write and erase characteristics of a memory cell manufactured by the manufacturing method according to the third embodiment and a memory cell manufactured by the manufacturing method according to the second embodiment, which differ from each other only in structure of the tunnel insulating film. As can be seen from FIG. 24, the memory cell manufactured by the manufacturing method according to the third embodiment has improved write and erase characteristics, compared with those of the memory cell manufactured by the manufacturing method according to the second embodiment. This is because, in the third embodiment, the tunnel insulating film is a tunnel insulating film (a microcrystalline tunnel film) having a structure that includes a conductive fine particle (Si particle) layer (a microcrystalline layer) and two insulating layers (SiO₂ layers) that are designed to sandwich the microcrystalline layer. The write and erase characteristics are improved, also because the Coulomb blockade conditions are satisfied, or the diameter of the conductive fine particles (the quantum dots) is 2 nm or smaller, with which ΔE rapidly increases. As a result, the electron and hole injection efficiency for writing and erasing is improved on the high-field side. As shown in FIG. 25(a), the microcrystalline tunnel film has a structure in which Si quantum dots of 2 nm or smaller in particle size are included in the SiO₂ layers. Since Si is supplied in the form of quantum dots, a Coulomb blockade effect is achieved to increase the barriers of electrons and holes in the quantum dots by ΔE=e²/2C(C: the capacitance of the quantum dots). Accordingly, as shown in FIG. 25(b), the barrier increase becomes larger, as the diameter d of the quantum dots becomes smaller. Where the diameter d is 2 nm or smaller, a remarkable effect is achieved.

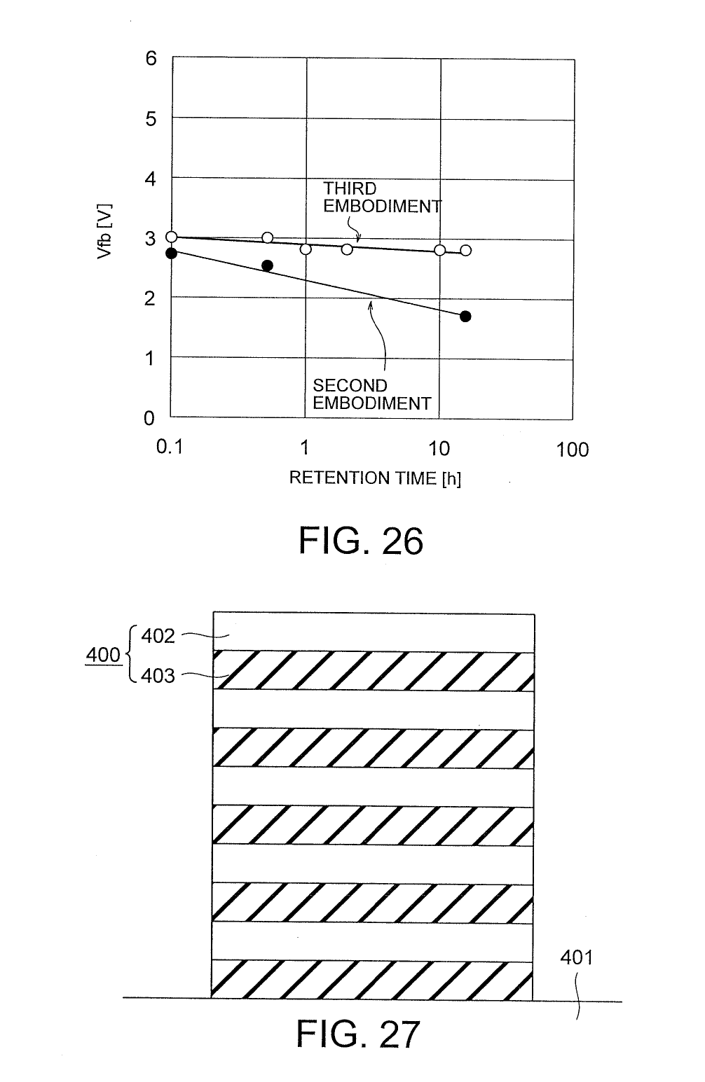

FIG. 26 shows the data retention characteristics of a memory cell manufactured by the manufacturing method according to the third embodiment and a memory cell manufactured by the manufacturing method according to the second embodiment. As can be seen from FIG. 26, the retention characteristics are improved where the tunnel insulating film is a microcrystalline tunnel film. This is because, while electrons and holes hardly escape on the low-field side by virtue of the Coulomb blockade effect, the effect of ΔE (the width of the energy barrier between the conduction band and the valence band of Si, which increases with the Coulomb blockade effect) becomes smaller on the high-field side through which carriers are injected, and equivalent write and erase characteristics can be achieved.

As described so far, according to this embodiment, electrons are restrained from escaping from the charge trapping film, and degradation of retention characteristics due to miniaturization can be prevented as much as possible.

### Fourth Embodiment

Next, a method of manufacturing a nonvolatile semiconductor memory device according to a fourth embodiment of the present invention is described. The nonvolatile semiconductor memory device to be manufactured by the manufacturing method according to this embodiment is a MONOS semiconductor memory that has a stacked structure in which control gates made of doped polysilicon or the like and interlayer insulating films that are silicon oxide films or the like are deposited on one another. This MONOS semiconductor memory includes memory cells. Referring now to FIGS. 27 through 29, the method of manufacturing the semiconductor memory according to this embodiment is described.

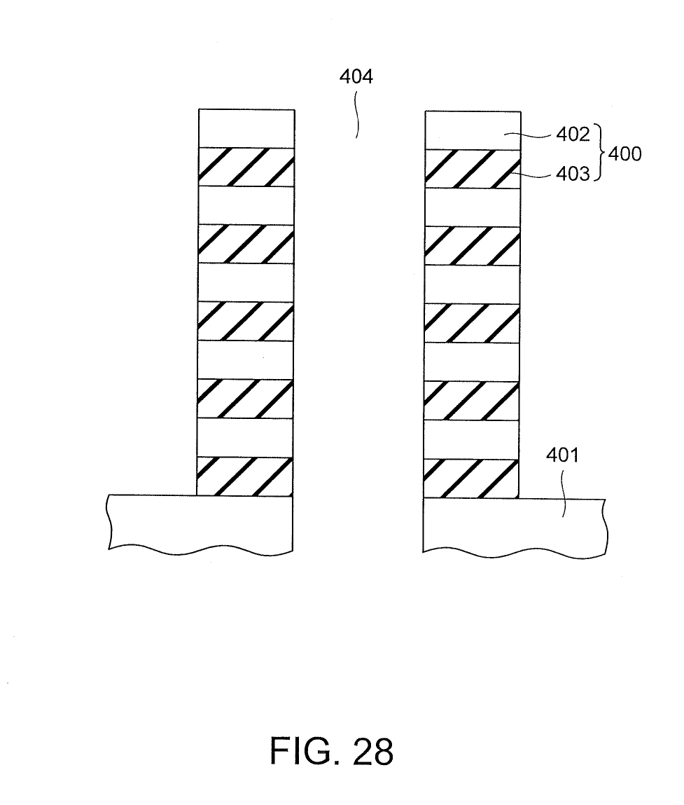

First, a stacked structure 400 in which control gates 402 made of doped polysilicon or the like and interlayer insulating films 403 that are silicon oxide films or the like are deposited on one another is formed on a substrate 401 (FIG. 27). An opening 404 is then formed in the stacked structure 400 and the substrate 401 by dry etching (FIG. 28). A protection film (not shown) is formed to cover the portions (the outer sides and the upper faces) other than the portion in which the opening 404 is formed in the stacked structure 400. This stacked structure 400 is put into a chamber, and a block insulating film 405 that is a high-permittivity insulating film or a silicon oxide film is formed on the inner walls of the opening 404.

The temperature of the substrate 401 is then adjusted to 700° C., for example, while dichlorosilane and NH₃ are being supplied. As a result of this, a silicon nitride layer 406a having a layer thickness of 1 nm is formed to cover the surface of the inner side (the opposite side from the stacked structure 400) of the block insulating film 405 formed on the inner walls of the opening 404. The temperature of formation of the silicon nitride layer 406a is preferably 550° C. or higher. The atmosphere in the chamber is then turned into a mixed gas atmosphere of N₂ of 30 Torr in partial pressure and O₂ of 0.03 Torr in partial pressure, for example, and the surface of the silicon substrate 401 is adjusted to and maintained at 950° C. for 10 seconds. As a result of this, the surface of the inner side (the opposite side from the block insulating film 405) of the silicon nitride layer 406a is oxidized to generate interstitial Si, and a silicon oxynitride layer 406b is formed. At this point, the silicon nitride layer 406a is a layer continuing in the in-plane direction, and has three-coordinate bonds. Also, the silicon nitride layer 406a has a structure in which at least one of the second-neighbor atoms of nitrogen is a nitrogen atom. Dichlorosilane and NH₃ are then supplied, to deposit a 1-nm silicon nitride layer 406c to cover the surface of the inner side (the opposite side from the silicon nitride layer 406a) of the silicon oxynitride layer 406b. At this point, the temperature of the silicon substrate 401 is preferably 550° C. or higher. In this embodiment, the temperature of the silicon substrate 401 is 700° C., for example. The atmosphere in the chamber remains a mixed gas atmosphere of N₂ of 30 Torr in partial pressure and O₂ of 0.03 Torr in partial pressure, for example, and the surface of the silicon substrate 401 is adjusted to and maintained at 950° C. for 10 seconds. As a result of this, the surface of the inner side (the opposite side from the silicon oxynitride layer 406b) of the silicon nitride layer 406c is oxidized to generate interstitial Si, and a silicon oxynitride layer 406d is formed. At this point, the silicon nitride layer 406c is a layer continuing in the in-plane direction, and has three-coordinate bonds. Also, the silicon nitride layer 406c has a structure in which at least one of the second-neighbor atoms of nitrogen is a nitrogen atom. Dichlorosilane and NH₃ are then supplied into the chamber, to deposit a 1-nm silicon nitride layer 406e to cover the surface of the inner side (the opposite side from the silicon nitride layer 406c) of the silicon oxynitride layer 406d. At this point, the temperature of the silicon substrate 401 is preferably 550° C. or higher. In this embodiment, the temperature of the silicon substrate 401 is 630° C., for example. As a result of this, a charge trapping film 406 that has a five-layer structure consisting of the silicon nitride layer 406a, the silicon oxynitride layer 406b, the silicon nitride layer 406c, the silicon oxynitride layer 406d, and the silicon nitride layer 406e is formed on the inner walls of the opening 404.

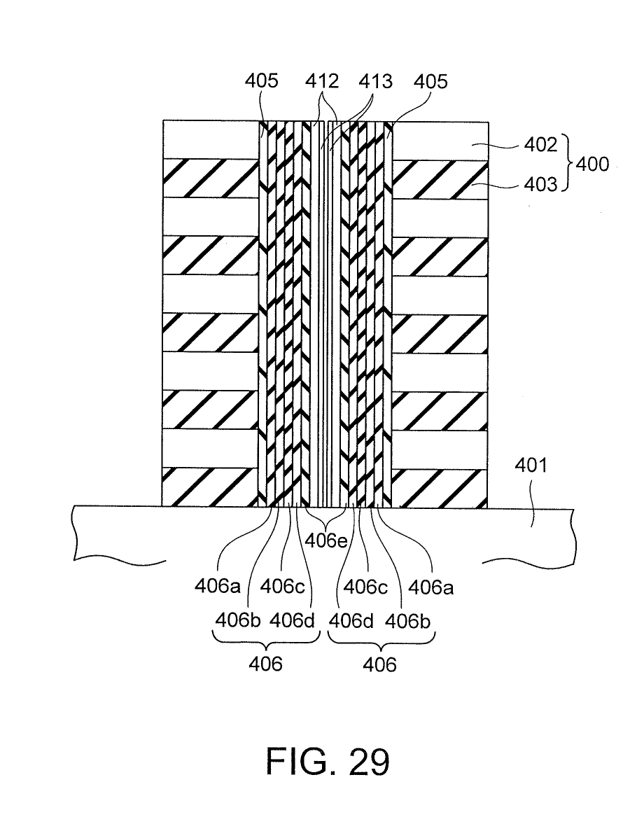

A tunnel insulating film 412 that is a silicon oxide film or the like is then formed to cover the surface of the inner side (the opposite side from the block insulating film 405) of the charge trapping film 406. A channel semiconductor layer 413 made of amorphous silicon or the like is then formed to cover the surface of the inner side (the opposite side from the charge trapping film 406) of the tunnel insulating film 412 (FIG. 29).

The tunnel insulating film 412 may be a silicon oxide film formed by the same technique as that for the block insulating film 405, or may be a silicon oxynitride film formed by further nitriding the silicon oxide film in a nitric oxide gas atmosphere, an ammonia gas atmosphere, or a nitrogen plasma atmosphere. Further, in a case where a tunnel insulating film having an ONO structure is used, a silicon nitride film is formed by ALD, LPCVD, or plasma nitriding, while the above silicon oxide film is being formed. This film formation is performed by using dichlorosilane (SiH₂Cl₂) and ammonia (NH₃) at a temperature of 300 to 500° C. in the case of ALD and at a temperature of 600 to 800° C. in the case of LPCVD.

Furthermore, using ALD or CVD is advantageous, because the block insulating film, the charge trapping film, and the tunnel insulating film can be collectively formed in the same apparatus. This contributes to a cost reduction through a reduction in the number of procedures. In addition to that, unnecessary interface states generated between the respective films can be reduced, and accordingly, degradation of cells over time after application of write or erase stress can be restrained.

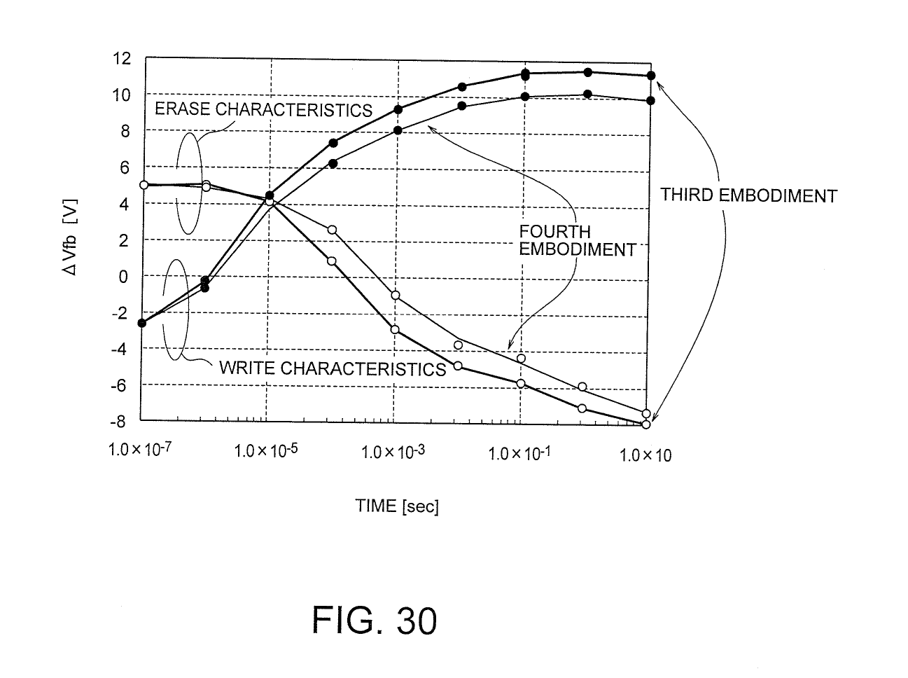

FIG. 30 shows the write and erase characteristics of a memory cell having a MONOS structure manufactured by the manufacturing method according to this embodiment and a memory cell manufactured by the manufacturing method according to the third embodiment. As can be seen from FIG. 30, the memory cell manufactured by the manufacturing method according to the fourth embodiment has greatly improved write and erase characteristics, compared with those of the memory cell manufactured by the manufacturing method according to the third embodiment. This is because the control gates are provided to surround the charge trapping film so that the electric field applied to the tunnel insulating film side becomes larger than that applied to the block insulating film side at the time of writing or erasing.

As described so far, according to this embodiment, electrons are prevented from escaping from the charge trapping film. Accordingly, degradation of retention characteristics due to miniaturization can be prevented as much as possible. Also, memory windows can be made even larger with semiconductor memories having structures manufactured by the manufacturing method according to this embodiment.

In the fourth embodiment, after the block insulating film 405 is formed, the charge trapping film 406 is formed by using the same procedures as the manufacturing procedures according to the second embodiment. The charge trapping film 406 may be formed by using the same procedures as the procedures for manufacturing the charge trapping film according to the first or third embodiment.

In the first through fourth embodiments, each silicon nitride layer having three-coordinate bonds is directly formed by using dichlorosilane and NH₃. Instead of the direct formation of a silicon nitride layer, an amorphous silicon layer may be formed by supplying an amorphous silicon generating gas in an atmosphere at a temperature of 550° C. or lower, which is a suitable temperature for generating amorphous silicon. After that, at a temperature of 550° C. or higher, the amorphous silicon layer may be nitrided to form a silicon nitride layer. This method was invented by the inventors of the present invention, and the applicant has already applied for a patent on this method (Japanese Patent Application No. 2008-224448).

While certain embodiments have been described, these embodiments have been presented by way of example only, and are not intended to limit the scope of the inventions. Indeed, the novel methods and systems described herein can be embodied in a variety of other forms; furthermore, various omissions, substitutions and changes in the form of the methods and systems described herein can be made without departing from the spirit of the inventions. The accompanying claims and their equivalents are intended to cover such forms or modifications as would fall within the scope and spirit of the inventions.

1. A method of manufacturing a nonvolatile semiconductor memory device, comprising:
forming a first insulating film on a semiconductor substrate;
forming a charge trapping film on the first insulating film, the forming of the charge trapping film comprising;
forming a first nitride layer on the first insulating film at a heat treatment temperature of 550° C. or higher,
forming a first oxynitride layer on the first nitride layer by oxidizing a surface of the first nitride layer, and
forming a second nitride layer on the first oxynitride layer;
forming a second insulating film on the charge trapping film; and
forming a control gate on the second insulating film.

2. The method according to claim 1, wherein the oxidizing for forming the first oxynitride layer is performed at 950° C. or higher in a time of 10 seconds or shorter.

3. The method according to claim 1, wherein the first nitride layer has three-coordinate bonds, and has at least two nitrogen atoms existing as second-neighbor atoms of nitrogen.

4. The method according to claim 1, wherein
the second nitride layer is formed at a temperature of 550° C. or higher, and
the method further comprising:
forming a second oxynitride layer on the second nitride layer by oxidizing a surface of the second nitride layer; and
forming a third nitride layer on the second oxynitride layer,
the second oxynitride layer and the third nitride layer being formed after the second nitride layer is formed.

5. The method according to claim 1, wherein
the forming of the first nitride layer comprises:
forming an amorphous silicon layer including microcrystalline silicon or fine silicon; and
nitriding the amorphous silicon layer at a heat treatment temperature of 550° C. or higher.

6. A method of manufacturing a nonvolatile semiconductor memory device, comprising:
forming a stacked structure comprising control gates and interlayer insulating films alternately stacked;
forming an opening through the stacked structure in a direction perpendicular to a plane in which the control gates and the interlayer insulating films are stacked;
forming a first insulating film in the opening, the first insulating film covering side faces in the opening of the stacked structure;
forming a charge trapping film in the opening, the charge trapping film covering a first face of the first insulating film, the first face being on the opposite side from the stacked structure, the forming of the charge trapping film comprising;
forming a first nitride layer at a heat treatment temperature of 550° C. or higher, the first nitride layer covering the first face of the first insulating film,
forming a first oxynitride layer on the surface of the first nitride layer by oxidizing the surface of the first nitride layer, the surface being on the opposite side from the first insulating film, and
forming a second nitride layer to cover a second face of the first oxynitride layer, the second face being on the opposite side from the first nitride layer;
forming a second insulating film in the opening, the second insulating film covering a third face of the charge trapping film, the third face being on the opposite side from the first insulating film; and
forming a semiconductor layer in the opening, the semiconductor layer covering a fourth face of the second insulating film, the fourth face being on the opposite side from the charge trapping film.

7. A nonvolatile semiconductor memory device comprising:
a first insulating film formed on a semiconductor substrate;
a charge trapping film comprising a first nitride layer formed on the first insulating film, a first oxynitride layer formed on the first nitride layer, and a second nitride layer formed on the first oxynitride layer;
a second insulating film formed on the charge trapping film; and
a control gate formed on the second insulating film.

8. The device according to claim 7, wherein the charge trapping film further comprises a second oxynitride layer formed on the second nitride layer, and a third nitride layer formed on the second oxynitride layer.

9. The device according to claim 7, wherein the first nitride layer has three-coordinate bonds, and comprises at least two nitrogen atoms existing as second-neighbor atoms of nitrogen.

10. The device according to claim 7, wherein the first insulating film comprises a first insulating layer, a second insulating layer, and a conducive fine particle layer interposed between the first insulating layer and second insulating layer, the conductive fine particle layer satisfying a Coulomb blockade condition.

11. The device according to claim 7, wherein the charge trapping film has an oxygen concentration peak in a film other than interfaces with the first and second insulating films.

12. A nonvolatile semiconductor memory device comprising:
a stacked structure comprising control gates and interlayer insulating films alternately stacked, and having a through hole formed in a direction perpendicular to a plane in which the control gates and the interlayer insulting films are stacked;
a first insulating film formed in the through hole, the first insulating film covering side faces in the through hole of the stacked structure;
a charge trapping film including: a first nitride layer formed to cover a first face of the first insulating film, the first face being on the opposite side from the stacked structure; a first oxynitride layer formed to cover a second face of the first nitride layer, the second face being on the opposite side from the first insulating film; and a second nitride layer formed to cover a third face of the first oxynitride layer, the third face being on the opposite side from the first nitride layer;
a second insulating film formed in the through hole, the second insulating film covering a fourth face of the charge trapping film, the fourth face being on the opposite side from the first insulating film; and
a semiconductor layer formed in the through hole, the semiconductor layer covering a fifth face of the second insulating film, the fifth face being on the opposite side from the charge trapping film.
